(19) United States
(12) Patent Application Publication
(10) Pub. No.: US 2026/0006808 A1
(43) Pub. Date: Jan. 1, 2026

(54) CAPACITOR STRUCTURE AND SEMICONDUCTOR MEMORY DEVICE INCLUDING THE SAME

(71) Applicant: Samsung Electronics Co., Ltd., Suwon-si (KR)

(72) Inventors: Min Hee CHO, Suwon-si (KR); Tae Jin PARK, Suwon-si (KR)

(73) Assignee: Samsung Electronics Co., Ltd., Suwon-si (KR)

(21) Appl. No.: 19/061,305

(22) Filed: Feb. 24, 2025

(30) Foreign Application Priority Data
Jun. 27, 2024 (KR) 10-2024-0084718

(51) Int. Cl. H10D 1/68; H10B 12/00

(52) U.S. Cl. CPC H10D 1/716; H10B 12/312; H10B 12/37; H10B 12/482; H10B 12/488

(57) ABSTRACT

There is provided a capacitor structure which is formed using a fabricating method in which a plate electrode is formed before a capacitor dielectric film. The capacitor structure includes a plate electrode which defines an electrode mold trench, an electrode mold insulating pattern which is in contact with the plate electrode, and includes a side wall part disposed on a side wall of the electrode mold trench, and a bottom part disposed on a bottom face of the electrode mold trench, a first capacitor electrode which is disposed on the bottom part of the electrode mold insulating pattern, and extends in a first direction, a capacitor dielectric film which is disposed on the side wall of the first capacitor electrode, and a second capacitor electrode which is disposed on the capacitor dielectric film and connected to the plate electrode.

### CROSS-REFERENCE TO RELATED APPLICATION

This application claims priority from Korean Patent Application No. 10-2024-0084718 filed on Jun. 27, 2024 in the Korean Intellectual Property Office and all the benefits accruing therefrom under 35 U.S.C. 119, the contents of which in its entirety are herein incorporated by reference.

### BACKGROUND

### 1. Field of the Disclosure

The present disclosure relates to capacitor structures and semiconductor memory devices including the same, and more specifically, to semiconductor memory devices including a capacitor structure and a vertical channel transistor (VCT).

### 2. Description of the Related Art

It may be advantageous to increase the degree of integration of a semiconductor memory device to improve performance and/or lower a price paid by consumers. Because the degree of integration may be a factor in determining the price of a product in the case of the semiconductor memory device, an increased degree of integration may be advantageous.

In the case of a two-dimensional or planar semiconductor memory device, the degree of integration is mainly determined by an area occupied by unit memory cells, and is therefore affected by the granularity of a fine pattern forming technique. However, since ultra-expensive apparatuses may be required to reduce or miniaturize the pattern, the degree of integration of the two-dimensional semiconductor memory device may increase, but may still be limited. Accordingly, semiconductor memory devices including vertical channel transistors with channels extending in a vertical direction have been proposed.

### SUMMARY

Aspects of the present disclosure provide capacitor structures which are formed using a fabricating method in which a plate electrode is formed before a capacitor dielectric film.

Aspects of the present disclosure also provide semiconductor memory devices having improved degree of integration and/or electrical characteristics.

However, aspects of the present disclosure are not restricted to the one set forth herein. The above and other aspects of the present disclosure will become more apparent to one of ordinary skill in the art to which the present disclosure pertains by referencing the detailed description of the present disclosure given below.

According to some aspects of the present disclosure, there is provided a capacitor structure including, a plate electrode defining an electrode mold trench, an electrode mold insulating pattern in contact with the plate electrode, the electrode mold insulating pattern including a side wall part on a side wall of the electrode mold trench, and a bottom part on a bottom face of the electrode mold trench, a first capacitor electrode on the bottom part of the electrode mold insulating pattern, and extending in a first direction, a capacitor dielectric film on the side wall of the first capacitor electrode, and a second capacitor electrode on the capacitor dielectric film and connected to the plate electrode.

According to some aspects of the present disclosure, there is provided a semiconductor memory device including, a contact pattern on a substrate, the contact pattern including a first face and a second face that are opposite to each other in a first direction, a capacitor structure between the substrate and the contact pattern and connected to the first face of the contact pattern, a channel pattern connected to the second face of the contact pattern, a bit line on the channel pattern and extending in a second direction, and a word line on the channel pattern between the bit line and the contact pattern, and extending in a third direction, the capacitor structure including, a plate electrode defining an electrode mold trench, an electrode mold insulating pattern including a side wall part on a side wall of the electrode mold trench, and a bottom part on a bottom face of the electrode mold trench, a first capacitor electrode on the bottom part of the electrode mold insulating pattern, and connected to the first face of the contact pattern, a capacitor dielectric film on the first capacitor electrode, and a second capacitor electrode on the capacitor dielectric film and connected to the plate electrode.

According to some aspects of the present disclosure, there is provided a semiconductor memory device including, a contact pattern on a substrate, the contact pattern including a first face and a second face that are opposite to each other in a first direction, a capacitor structure between the substrate and the contact pattern and connected to the first face of the contact pattern, a channel pattern connected to the second face of the contact pattern, a bit line on the channel pattern and extending in a second direction, and a word line on the channel pattern between the bit line and the contact pattern and extending in a third direction, the capacitor structure including, a plate electrode defining an electrode mold trench, an electrode mold insulating pattern filling the electrode mold trench and including a mold insulating hole, a first capacitor electrode extending along a side wall and a bottom face of the mold insulating hole, and connected to the plate electrode, a capacitor dielectric film on the first capacitor electrode, and extending along a side wall and a bottom face of the mold insulating hole, and a second capacitor electrode on the capacitor dielectric film, filling the mold insulating hole, and connected to the first face of the contact pattern, the bottom face of the mold insulating hole defined by the plate electrode.

### BRIEF DESCRIPTION OF THE DRAWINGS

The above and other aspects and features of the present disclosure will become more apparent by describing in detail some example embodiments thereof with reference to the attached drawings, in which:

FIG. 1 is a schematic layout diagram of a semiconductor memory device according to some example embodiments.

FIG. 2 is a layout diagram of a boundary portion between a cell array region and a peripheral circuit region of FIG. 1.

FIG. 3 is a cross-sectional view taken along A-A and B-B of FIG. 2.

FIG. 4 is a cross-sectional view taken along C-C and D-D of FIG. 2.

FIG. 5 is an enlarged view of a portion P of FIG. 3.

FIG. 6 is an enlarged view of a portion Q of FIG. 3.

FIG. 7 is a perspective view for explaining a shape of a plate electrode of FIG. 3.

FIG. 8 is a perspective view showing a first capacitor electrode and a second capacitor electrode separated from each other in a capacitor structure of FIG. 3.

FIG. 9 is a diagram for explaining a shape of a bottom part of a first electrode mold insulating pattern in the capacitor structure of FIG. 3.

FIGS. 10 and 11 are diagrams for explaining a semiconductor memory device according to some example embodiments.

FIGS. 12 and 13 are diagrams for explaining a semiconductor memory device according to some example embodiments.

FIG. 14 is a diagram for explaining a semiconductor memory device according to some example embodiments.

FIGS. 15 to 18 are diagrams for explaining a semiconductor memory device according to some example embodiments.

FIG. 19 is a diagram for explaining a semiconductor memory device according to some example embodiments.

FIGS. 20 to 23 are diagrams for explaining a semiconductor memory device according to some example embodiments.

FIGS. 24 and 25 are diagrams for explaining a semiconductor memory device according to some example embodiments.

FIGS. 26 to 29 are diagrams for explaining a semiconductor memory device according to some example embodiments, respectively.

FIGS. 30 to 37 are intermediate stage diagrams for explaining a method for fabricating a semiconductor memory device according to some example embodiments.

FIGS. 38 to 42 are intermediate stage diagrams for explaining a method for fabricating a semiconductor memory device according to some example embodiments.

### DETAILED DESCRIPTION

It will be understood that, although the terms “first”, “second”, etc. may be used herein to describe various elements or components, these elements or components should not be limited by these terms. These terms are only used to distinguish one element or component from another element or component. Therefore, a first element or component discussed below could be termed a second element or component without departing from the technical spirits of the present disclosure.

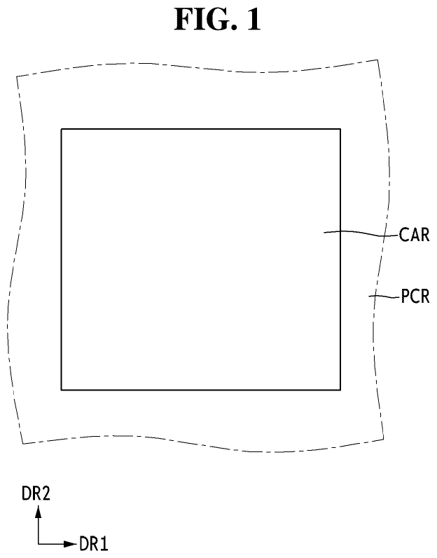

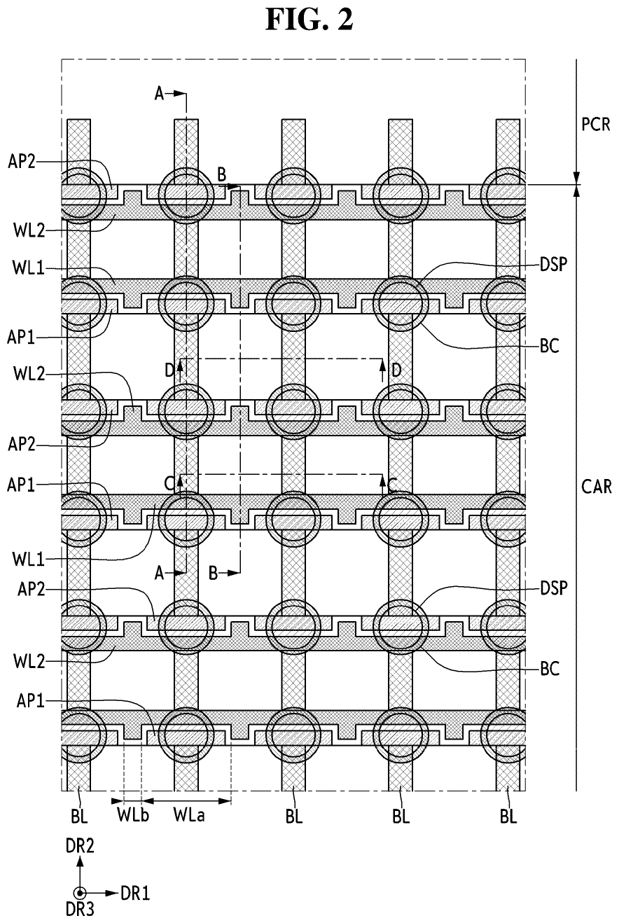

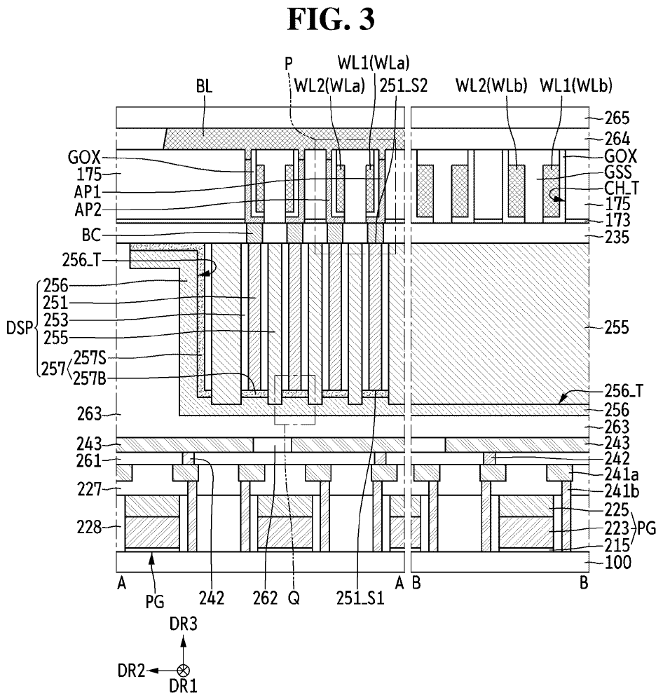

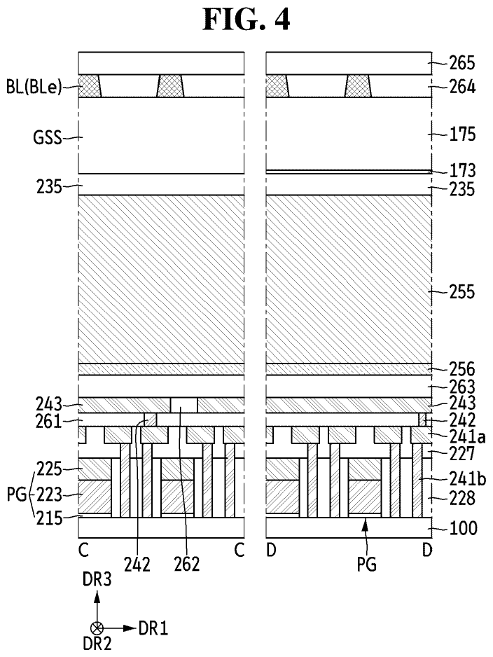

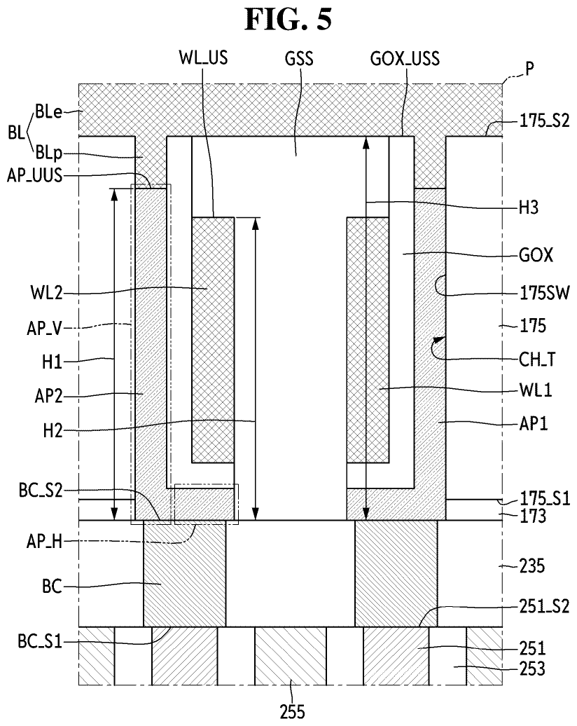

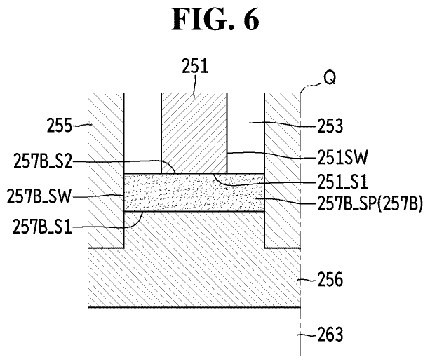

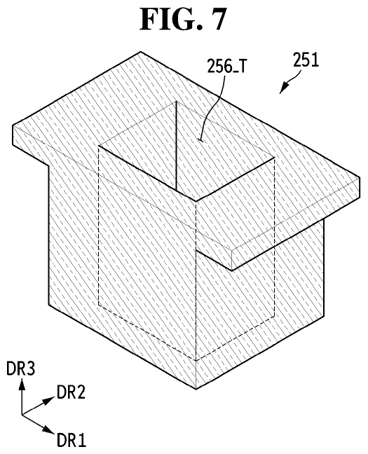

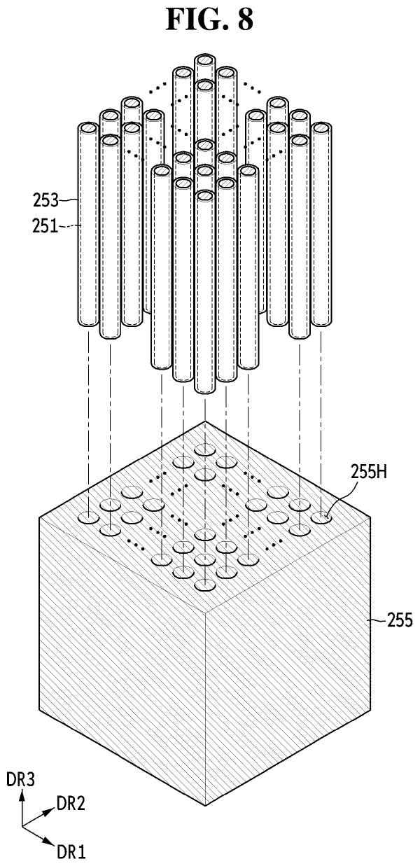

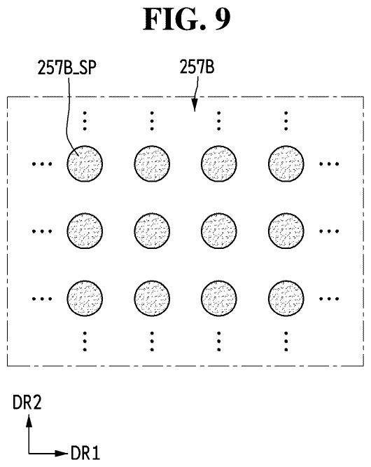

FIG. 1 is a schematic layout diagram of a semiconductor memory device according to some example embodiments. FIG. 2 is a layout diagram of a boundary portion between a cell array region and a peripheral circuit region of FIG. 1. FIG. 3 is a cross-sectional view taken along A-A and B-B of FIG. 2. FIG. 4 is a cross-sectional view taken along C-C and D-D of FIG. 2. FIG. 5 is an enlarged view of a portion P of FIG. 3. FIG. 6 is an enlarged view of a portion Q of FIG. 3. FIG. 7 is a perspective view for explaining a shape of a plate electrode of FIG. 3. FIG. 8 is a perspective view showing a first capacitor electrode and a second capacitor electrode separated from each other in a capacitor structure of FIG. 3. FIG. 9 is a diagram for explaining a shape of a bottom part of a first electrode mold insulating pattern in the capacitor structure of FIG. 3.

For reference, in FIG. 2, a capacitor structure DSP is indicated at a point where a first capacitor electrode 251 is located.

The semiconductor memory device according to the embodiment of the present disclosure may include memory cells including a vertical channel transistor (VCT).

Referring to FIGS. 1 to 9, the semiconductor memory device according to some example embodiments includes a peri-gate structure PG, bit lines BL, word lines WL1 and WL2, first channel patterns AP1, second channel patterns AP2, contact patterns BC, and a capacitor structure DSP.

The substrate 100 may include a cell array region CAR in which the capacitor structure DSP is disposed, and a peripheral circuit region PCR defined around the cell array region CAR. The substrate 100 may be a silicon substrate or may include other materials, for example, but not limited to, silicon germanium, indium antimonide, lead telluride, indium arsenide, indium phosphide, gallium arsenide and/or gallium antimonide.

The peri-gate structure PG may be disposed on the substrate 100. The substrate 100 may include a cell array region CAR and a peripheral circuit region PCR. The peri-gate structure PG may be disposed over the cell array region CAR and the peripheral circuit region PCR. In other words, a part of the peri-gate structure PG may be disposed in the cell array region CAR of the substrate 100, and the remainder of the peri-gate structure PG may be disposed in the peripheral circuit region PCR of the substrate 100.

The peri-gate structure PG may be included in a sensing transistor, a transfer transistor, a driving transistor, and the like. However, the type of transistor disposed in the cell array region CAR and the peripheral circuit region PCR may vary depending on the design placement of the semiconductor memory device.

The peri-gate structure PG may include a peri-gate insulating film 215, a peri-lower conductive pattern 223, and a peri-upper conductive pattern 225. The peri-gate insulating film 215 may include a silicon oxide film, a silicon oxynitride film, a high dielectric constant insulating film having a higher dielectric constant than the silicon oxide film, or a combination thereof. The high dielectric constant insulating film may include, but not limited to, at least one of, for example, a metal oxide, a metal oxynitride, a metal silicon oxide, and/or a metal silicon oxynitride.

Each of the peri-lower conductive pattern 223 and the peri-upper conductive pattern 225 may include a conductive material. For example, each of the peri-lower conductive pattern 223 and the peri-upper conductive pattern 225 may include at least one of a doped semiconductor material, a conductive metal nitride, a conductive metal silicon nitride, a metal carbonitride, a conductive metal silicide, a conductive metal oxide, a two-dimensional material (2D material), a metal, and/or a metal alloy. The peri-gate structure PG is shown to include, but not limited to, a plurality of conductive patterns.

In the semiconductor device according to some example embodiments, the 2D material may be a metallic material and/or a semiconductor material. The 2D material may include a 2D allotrope or a 2D compound, and may include, for example, but not limited to, at least one of graphene, molybdenum disulfide (MoS₂), molybdenum diselenide (MoSe₂), tungsten diselenide (WSe₂), and/or tungsten disulfide (WS₂). That is, since the above-mentioned 2D materials are only listed as an example, the 2D materials that may be included in the semiconductor memory device of the present disclosure are not limited by the above-mentioned materials.

A first peri-lower insulating film 227 and a second peri-lower insulating film 228 are disposed on the substrate 100. Each of the first peri-lower insulating film 227 and the second peri-lower insulating film 228 may be made of an insulating material.

The second peri-lower insulating film 228 is shown to come into contact with the side walls of the peri-lower conductive pattern 223 and the peri-upper conductive pattern 225, but is the inventive concepts are not limited thereto. The peri-gate structure PG may include a peri-gate spacer which is disposed on a side wall of the peri-lower conductive pattern 223 and a side wall of the peri-upper conductive pattern 225.

A peri-wiring line 241a and a peri-contact plug 241b may be disposed inside the first peri-lower insulating film 227 and the second peri-lower insulating film 228. The peri-contact plug 241b may be connected to a source/drain region disposed on at least one side of the peri-gate structure PG. For example, the source/drain region may be, but not limited to, a region in which impurities are doped in the substrate 100. Although not shown, the peri-contact plug 241b may be connected to the peri-conductive patterns 223 and 225 of the peri-gate structure PG.

The peri-wiring line 241a may be disposed on the peri-contact plug 241b. The peri-wiring line 241a is connected to the peri-contact plug 241b. For example, the peri-wiring line 241a may be a wiring line that is closest to the peri-gate structure PG in a third direction DR3.

The peri-wiring line 241a and the peri-contact plug 241b are shown as being different films from each other, but are not limited thereto. A boundary between the peri-wiring line 241a and the peri-contact plug 241b may not be distinguished. The peri-wiring line 241a and the peri-contact plug 241b each include a conductive material.

The first peri-upper insulating film 261 and the second peri-upper insulating film 262 may be disposed on the peri-wiring line 241a and the peri-contact plug 241b. The first peri-upper insulating film 261 and the second peri-upper insulating film 262 may each be made of an insulating material.

A peri-connecting wiring 243 and a peri-connecting via 242 may be disposed on the peri-wiring line 241a. The peri-connecting via 242 may be disposed inside the first peri-upper insulating film 261. The peri-connecting wiring 243 may be disposed inside the second peri-upper insulating film 262.

The peri-connecting wiring 243 and the peri-connecting via 242 may be connected to the peri-wiring line 241a. The peri-connecting via 242 may connect the peri-wiring line 241a and the peri-connecting wiring 243. The peri-connecting wiring 243 and the peri-connecting via 242 each include a conductive material. The peri-connecting wiring 243 and the peri-connecting via 242 are shown as being different films from each other, but are not limited thereto. The boundary between the peri-connecting wiring 243 and the peri-connecting via 242 may not be distinguished, e.g., the peri-connecting wiring 243 and the peri-connecting via 242 may be integral.

The peri-connecting wiring disposed at one metal level is shown as being disposed on the peri-wiring line 241a, but this is only for convenience of explanation, and the inventive concepts are not limited thereto. However, in some example embodiments, a plurality of peri-connecting wirings 243 disposed at different metal levels from each other may be disposed on the peri-wiring line 241a.

A first interlayer insulating film 263 may be disposed on the peri-connecting wiring 243. The first interlayer insulating film 263 may include an insulating material. The first interlayer insulating film 263 is shown as being a single film, but is not limited thereto.

A capacitor structure DSP may be disposed on the peri-connecting wiring 243. The capacitor structure DSP may be disposed inside the first interlayer insulating film 263.

In the semiconductor memory device according to some example embodiments, the capacitor structure DSP may include a first capacitor electrode 251, a capacitor dielectric film 253, a second capacitor electrode 255, a plate electrode 256, and a first electrode mold insulating pattern 257.

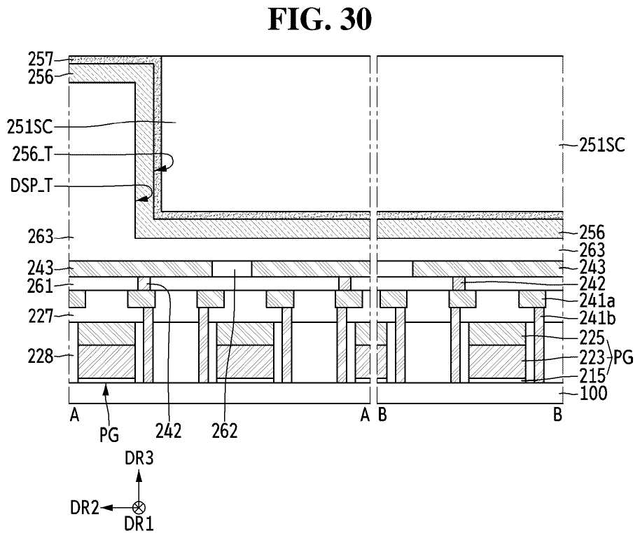

The plate electrode 256 may have a hollow cylindrical shape. The plate electrode 256 may extend along the side wall and bottom face of the capacitor trench (DSP_T of FIG. 30).

The plate electrode 256 may define an electrode mold trench 256_T. The side wall and bottom face of the electrode mold trench 256_T may be defined by the plate electrode 256. The first capacitor electrode 251, the capacitor dielectric film 253, the second capacitor electrode 255, the plate electrode 256, and the first electrode mold insulating pattern 257 may be disposed inside the electrode mold trench 256_T.

The first electrode mold insulating pattern 257 may be disposed on the plate electrode 256. The first electrode mold insulating pattern 257 may come into contact with the plate electrode 256.

The first electrode mold insulating pattern 257 may include a bottom part 257B and a side wall part 257S. The side wall part 257S of the first electrode mold insulating pattern may be disposed on a side wall of the electrode mold trench 256_T. The side wall part 257S of the first electrode mold insulating pattern may extend along the side wall of the electrode mold trench 256_T.

The bottom part 257B of the first electrode mold insulating pattern may be disposed on a bottom face of the electrode mold trench 256_T. In the semiconductor memory device according to some example embodiments, the bottom part 257B of the first electrode mold insulating pattern may include a plurality of sub-electrode insulating patterns 257B_SP. The sub-electrode insulating patterns 257B_SP may be disposed to be spaced apart from each other in a first direction DR1 and a second direction DR2.

The sub-electrode insulating pattern 257B_SP may be disposed at a position corresponding to a first capacitor electrode 251 to be described below. That is, when the first capacitor electrodes 251 are arranged in a matrix shape, the sub-electrode insulating pattern 257B_SP may be disposed to correspond to the matrix shape arranged in the first capacitor electrodes 251.

Here, the first direction DR1 and the second direction DR2 may be orthogonal to the third direction DR3. The first direction DR1 may intersect the second direction DR2. For example, the third direction DR3 may be a thickness direction of the substrate 100. The first direction DR1 and the second direction DR2 may be parallel to an upper face of the substrate 100.

Each sub-electrode insulating pattern 257B_SP may include a first face 257B_S1 and a second face 257B_S2 that are opposite to each other in the third direction DR3. The sub-electrode insulating pattern 257B_SP may include a side wall 257B_SW that connects the first face 257B_S1 of the sub-electrode insulating pattern and the second face 257B_S2 of the sub-electrode insulating pattern.

The first face 257B_S1 of the sub-electrode insulating pattern may face the plate electrode 256. For example, the first face 257B_S1 of the sub-electrode insulating pattern may come into contact with the plate electrode 256.

The first face 257B_S1 of the sub-electrode insulating pattern may be a first face of the bottom part 257B of the first electrode mold insulating pattern. The second face 257B_S2 of the sub-electrode insulating pattern may be a second face of the bottom part 257B of the first electrode mold insulating pattern.

A plurality of first capacitor electrodes 251 may be disposed on the first electrode mold insulating pattern 257. Each first capacitor electrode 251 may be disposed on the bottom part 257B of the first electrode mold insulating pattern. For example, each first capacitor electrode 251 may come into contact with the bottom part 257B of the first electrode mold insulating pattern.

Each first capacitor electrode 251 may be disposed on a sub-electrode insulating pattern 257B_SP. The sub-electrode insulating pattern 257B_SP may be disposed between the plate electrode 256 and the first capacitor electrode 251.

Each first capacitor electrode 251 may extend long in the third direction DR3. For example, the first capacitor electrode 251 may have a pillar shape. The first capacitor electrodes 251 may be arranged in a matrix shape along the first direction DR1 and the second direction DR2, like the capacitor structure DSP shown in FIG. 2.

Each first capacitor electrode 251 may include a first face 251_S1 and a second face 251_S2 that are opposite to each other in the third direction DR3. The first capacitor electrode 251 may include a side wall 251SW that connects the first face 251_S1 of the first capacitor electrode and the second face 251_S2 of the first capacitor electrode.

The first face 251_S1 of the first capacitor electrode may face the bottom part 257B of the first electrode mold insulating pattern, e.g., the sub-electrode insulating pattern 257B_SP. The first face 251_S1 of the first capacitor electrode may come into contact with the first electrode mold insulating pattern 257. For example, the first face 251_S1 of the first capacitor electrode may come into contact with the sub-electrode insulating pattern 257B_SP. The first capacitor electrode may come into contact with the second face 257B_S2 of the sub-electrode insulating pattern. The first face 251_S1 of the first capacitor electrode may come into contact with the second face 257B_S2 of the sub-electrode insulating pattern.

From a planar viewpoint, the first capacitor electrode 251 may have various shapes such as a circle, an ellipse, a rectangle, a square, a rhombus, and a hexagon.

The capacitor dielectric film 253 may be disposed on the first capacitor electrode 251. The capacitor dielectric film 253 may be disposed on the side wall 251SW of the first capacitor electrode. The capacitor dielectric film 253 may extend along the side wall 251SW of the first capacitor electrode.

The capacitor dielectric film 253 may not be disposed between the first capacitor electrode 251 and the sub-electrode insulating pattern 257B_SP. The capacitor dielectric film 253 may not be disposed along the boundary between the first capacitor electrode 251 and the sub-electrode insulating pattern 257B_SP. The capacitor dielectric film 253 may not extend along the first face 251_S1 of the first capacitor electrode.

The capacitor dielectric film 253 may not be disposed between the plate electrode 256 and the sub-electrode insulating pattern 257B_SP. The capacitor dielectric film 253 may not be disposed along the boundary between the plate electrode 256 and the sub-electrode insulating pattern 257B_SP.

The capacitor dielectric film 253 may not be disposed on the side wall 257B_SW of the sub-electrode insulating pattern. The capacitor dielectric film 253 may not extend along the side wall 257B_SW of the sub-electrode insulating pattern.

The second capacitor electrode 255 may be disposed on the capacitor dielectric film 253. The second capacitor electrode 255 may be connected to the plate electrode 256.

The second capacitor electrode 255 is not disposed along the boundary between the first capacitor electrode 251 and the sub-electrode insulating pattern 257B_SP. The second capacitor electrode 255 is not disposed along the boundary between the plate electrode 256 and the sub-electrode insulating pattern 257B_SP.

The second capacitor electrode 255 may be disposed on the side wall 257B_SW of the sub-electrode insulating pattern. The second capacitor electrode 255 may extend along the side wall 257B_SW of the sub-electrode insulating pattern. For example, the second capacitor electrode 255 may come into contact with the side wall 257B_SW of the sub-electrode insulating pattern.

The lowermost part of the second capacitor electrode 255 is shown as being lower than the first face 257B_S1 of the sub-electrode insulating pattern on the basis of the upper face of the substrate 100, but the inventive concepts are not limited thereto. However, in some example embodiments, the lowermost part of the second capacitor electrode 255 may be disposed at the same or substantially the same height level as that of the first face 257B_S1 of the sub-electrode insulating pattern on the basis of the upper face of the substrate 100.

In FIGS. 3 and 8, the first electrode mold insulating pattern 257 may be disposed between the plate electrode 256 and the second capacitor electrode 255. The second capacitor electrode 255 may have a three-dimensional block shape including a plurality of second capacitor electrode holes 255H. Each second capacitor electrode hole 255H may penetrate the second capacitor electrode 255 in the third direction DR3.

The second capacitor electrode holes 255H may be formed at positions corresponding to the first capacitor electrodes 251. Each first capacitor electrode 251 may be disposed inside the corresponding second capacitor electrode hole 255H.

One first capacitor electrode 251 and the capacitor dielectric film 253 on the side wall 251SW of the first capacitor electrode may be disposed inside each second capacitor electrode hole 255H. The capacitor dielectric film 253 may extend along the side wall of the second capacitor electrode hole 255H.

The position of the second capacitor electrode hole 255H may correspond to each sub-electrode insulating pattern 257B_SP. Each sub-electrode insulating pattern 257B_SP may be disposed inside the corresponding second capacitor electrode hole 255H. That is, one first capacitor electrode 251 and one sub-electrode insulating pattern 257B_SP may be disposed inside one second capacitor electrode hole 255H.

The plate electrode 256 may include, for example, at least one of an elemental semiconductor material film or a compound semiconductor material film. The plate electrode 256 may include doped n-type impurities or p-type impurities. The elemental semiconductor material film may include, for example, either a silicon film and/or a germanium film. The compound semiconductor material film may include, for example, a silicon germanium film. The n-type impurities may include, for example, at least one of phosphorus (P), arsenic (As), antimony (Sb), and/or bismuth (Bi). The p-type impurities may include, for example, at least one of boron (B) and/or gallium (Ga). In the semiconductor memory device according to some example embodiments, the plate electrode 256 may include a silicon germanium film.

Each of the first capacitor electrode 251 and the second capacitor electrode 255 may include, for example, at least one of a conductive semiconductor material, a conductive metal nitride, a conductive metal silicon nitride, a conductive metal carbonitride, a conductive metal silicide, a conductive metal oxide, and/or a metal.

The capacitor dielectric film 253 may include at least one of a ferroelectric material, an antiferroelectric material, and/or a paraelectric material. For example, the capacitor dielectric film 253 may include one of the ferroelectric material, the antiferroelectric material, the paraelectric material, combinations of the ferroelectric material and the antiferroelectric material, combinations of the ferroelectric material and the paraelectric material, combinations of the paraelectric material and the antiferroelectric material, and combinations of the ferroelectric material, the antiferroelectric material and the paraelectric material.

The first electrode mold insulating pattern 257 may include an insulating material. The first electrode mold insulating pattern 257 may include, but not limited to, at least one of a silicon oxide, a silicon nitride, a silicon oxynitride, a silicon carbonitride, a silicon oxycarbide, and/or a silicon oxycarbonitride. In the semiconductor memory device according to some example embodiments, the first electrode mold insulating pattern 257 may include silicon nitride.

The contact patterns BC may be disposed on the capacitor structure DSP. Each of the contact patterns BC may be disposed on the first capacitor electrode 251. The first capacitor electrode 251 may come into contact with the contact patterns BC. From a planar viewpoint, the contact patterns BC may have various shapes, such as a circle, an ellipse, a rectangle, a square, a rhombus, and a hexagon, and further each of the contact patterns BC may each have various shapes.

A contact separation insulating film 235 may be disposed on the capacitor structure DSP and the first interlayer insulating film 263. The contact separation insulating film 235 may be disposed between the first channel pattern AP1 and the capacitor structure DSP, and between the second channel pattern AP2 and the capacitor structure DSP. The contact separation insulating film 235 may be disposed on the first capacitor electrode 251 and the second capacitor electrode 255. For example, the capacitor dielectric film 253 may not be disposed along the boundary between the second capacitor electrode 255 and the contact separation insulating film 235.

The contact separation insulating film 235 may be disposed between the contact patterns BC. The contact patterns BC may be disposed inside the contact separation insulating film 235. The contact patterns BC may be arranged in a matrix shape along the first direction DR1 and the second direction DR2 from a planar viewpoint. The contact separation insulating film 235 may be made of an insulating material.

The contact pattern BC may include a first face BC_S1 and a second face BC_S2 that are opposite to each other in the third direction DR3. The first face BC_S1 of the contact pattern may face a capacitor structure DSP.

The capacitor structure DSP may be connected to the first face BC_S1 of the contact pattern. The second face 251_S2 of the first capacitor electrode may be connected to the contact pattern BC. The first capacitor electrode 251 may come into contact with the first face BC_S1 of the contact pattern.

The first capacitor electrodes 251 may completely or partially overlap the contact patterns BC in the third direction DR3. The first capacitor electrode 251 may come into contact with all or a part of the first face BC_S1 of the contact pattern.

The contact pattern BC includes a conductive material. The contact pattern BC may include at least one of, for example, a doped polysilicon, a conductive metal nitride, a conductive metal silicon nitride, a metal carbonitride, a conductive metal silicide, a conductive metal oxide, a two-dimensional material, a metal, and/or a metal alloy.

A channel insulating film 175 may be disposed on the contact pattern BC and the contact separation insulating film 235. An etching stop film 173 may be disposed between the channel insulating film 175 and the contact separation insulating film 235.

The channel insulating film 175 may include a first face 175_S1 and a second face 175_S2 that are opposite to each other in the third direction DR3. The first face 175_S1 of the channel insulating film may face the contact pattern BC. For example, the first face 175_S1 of the channel insulating film may be a bottom face of the channel insulating film 175. The second face 175_S2 of the channel insulating film may be the upper face of the channel insulating film 175.

Each of the channel insulating film 175 and the etching stop film 173 may be made of an insulating material. The etching stop film 173 may include a material having an etching selectivity with respect to the channel insulating film 175. The channel insulating film 175 may be made of, but not limited to, an oxide-based insulating material including silicon. For example, the channel insulating film 175 may include silicon oxide.

However, in some example embodiments, the etching stop film 173 may not be disposed between the channel insulating film 175 and the contact separation insulating film 235. As another example, the channel insulating film 175 may include a plurality of insulating films stacked in the third direction DR3. For example, the channel insulating film 175 may include a silicon oxide film and a silicon nitride film that are stacked in the third direction DR3.

The channel insulating film 175 may include a plurality of channel trenches CH_T. Each channel trench CH_T may extend long in the first direction DR1. Adjacent channel trenches CH_T may be spaced apart in the second direction DR2.

Each channel trench CH_T may expose the contact pattern BC. At least a part of the second face BC_S2 of each contact pattern may be exposed by the channel trench CH_T.

The bottom face of each channel trench CH_T may be defined by the contact pattern BC and the contact separation insulating film 235. The side walls of each channel trench CH_T may be defined by the channel insulating film 175 and the etching stop film 173. At least a part of the side wall of the channel trench CH_T may be the side wall 175SW of the channel insulating film. When the etching stop film 173 is not disposed, the side walls of each channel trench CH_T may be defined by the channel insulating film 175.

The first channel pattern AP1 and the second channel pattern AP2 may be disposed on the capacitor structure DSP. The capacitor structure DSP may be disposed between the first channel pattern AP1 and the substrate 100. The capacitor structure DSP may be disposed between the second channel pattern AP2 and the substrate 100.

The first channel pattern AP1 and the second channel pattern AP2 may be disposed on the contact pattern BC. Each of the first channel pattern AP1 and the second channel pattern AP2 may be connected to the contact pattern BC. The first channel pattern AP1 and the second channel pattern AP2 may be connected to the second face BC_S2 of the contact pattern.

The first channel patterns AP1 may be spaced apart from each other in the first direction DR1. The first channel patterns AP1 may be spaced apart at regular intervals. The second channel patterns AP2 may be spaced apart from each other in the first direction DR1. The second channel patterns AP2 may be spaced apart at regular intervals. The first channel pattern AP1 may be spaced apart from the second channel pattern AP2 in the second direction DR2. The first and second channel patterns AP1 and AP2 may be two-dimensionally arranged along the first direction DR1 and the second direction DR2.

The first channel pattern AP1 and the second channel pattern AP2 may be disposed inside the channel trench CH_T extending in the first direction DR1. A plurality of first channel patterns AP1 may be disposed inside one channel trench CH_T. A plurality of second channel patterns AP2 may be disposed inside one channel trench CH_T.

Each of the first channel pattern AP1 and the second channel pattern AP2 may include a vertical part AP_V of the channel pattern and a horizontal part AP_H of the channel pattern.

The vertical part AP_V of the channel pattern may protrude from the second face BC_S2 of the contact pattern in the third direction DR3. The vertical part AP_V of the channel pattern may extend along a side wall of the channel trench CH_T. The vertical part AP_V of the channel pattern may extend along a side wall 175SW of the channel insulating film.

The horizontal part AP_H of the channel pattern may extend along the second face BC_S2 of the contact pattern. The horizontal part AP_H of the channel pattern may be directly connected to the vertical part AP_V of the channel pattern. From the viewpoint of a cross-sectional view, the horizontal part AP_H of the channel pattern may protrude from the vertical part AP_V of the channel pattern in the second direction DR2.

The first channel pattern AP1 and the second channel pattern AP2 may include an oxide semiconductor material. The first channel pattern AP1 and the second channel pattern AP2 may include, for example, a metal oxide. As an example, the first channel pattern AP1 and the second channel pattern AP2 may be amorphous metal oxide films. As another example, the first channel pattern AP1 and the second channel pattern AP2 may be polycrystalline metal oxide films. As yet another example, the first channel pattern AP1 and the second channel pattern AP2 may be in a combined status of the amorphous metal oxide film and the polycrystalline metal oxide film. As yet another example, the first channel pattern AP1 and the second channel pattern AP2 may be a CAAC (c-axis aligned crystalline) metal oxide film.

The first channel pattern AP1 and the second channel pattern AP2 may include, for example, but not limited to, at least one of indium oxide, tin oxide, zinc oxide, In—Zn-based oxide (IZO), Sn—Zn-based oxide, Al—Zn-based oxide, Zn—Mg-based oxide, Sn—Mg-based oxide, In—Mg-based oxide, In—Ga-based oxide (IGO), In—Ga—Zn-based oxide (IGZO), In—Al—Zn-based oxide, In—Sn—Zn-based oxide, Sn—Ga—Zn-based oxide, Al—Ga—Zn-based oxide, Sn—Al—Zn-based oxide, In—Hf—Zn-based oxide, In—La—Zn-based oxide, In—Ce—Zn-based oxide, In—Pr—Zn-based oxide, In—Nd—Zn-based oxide, In—Sm—Zn-based oxide, In—Eu—Zn-based oxide, In—Gd—Zn-based oxide, In—Tb—Zn-based oxide, In—Dy—Zn-based oxide, In—Ho—Zn-based oxide, In—Er—Zn-based oxide, In—Tm—Zn-based oxide, In—Yb—Zn-based oxide, In—Lu—Zn-based oxide, In—Sn—Ga—Zn-based oxide, In—Hf—Ga—Zn-based oxide, In—Al—Ga—Zn-based oxide, In—Sn—Al—Zn-based oxide, In—Sn—Hf—Zn-based oxide, and/or In—Hf—Al—Zn-based oxide.

Here, the In—Ga—Zn-based oxide means an oxide that has In, Ga, and Zn as main components, but does not mean a ratio of In, Ga, and Zn. That is, taking IGZO (indium gallium zinc oxide) as an example, the first channel pattern AP1 and the second channel pattern AP2 may include IGZO (indium gallium zinc oxide, InₓGa_{y}Zn_{z}O). The IGZO (In:Ga:Zn=1:1:1) containing indium, gallium and zinc at the same ratio may be an In-Ga—Zn-based oxide. A Ga-rich IGZO may have a higher ratio of gallium than the IGZO (In:Ga:Zn=1:1:1), and a lower ratio of indium than the IGZO (In:Ga:Zn=1:1:1). The Ga-rich IGZO may also be an In-Ga—Zn-based oxide. An In-rich IGZO may also have a higher ratio of indium than IGZO (In:Ga:Zn=1:1:1) and a lower ratio of gallium than IGZO (In:Ga:Zn=1:1:1). In-rich IGZO may also be an In-Ga—Zn-based oxide.

Although the above description has been made using the IGZO, the inventive concepts are not limited thereto. For example, according to some example embodiments, the above description may be applied when the first channel pattern AP1 and the second channel pattern AP2 each include a ternary or more metal oxide. Also, the first channel pattern AP1 and the second channel pattern AP2 may further include a doped metal element other than In, Ga, and Zn, when the first channel pattern AP1 and the second channel pattern AP2 include the In—Ga—Zn-based oxide.

A first word line WL1 may be disposed on the first channel pattern AP1. The second word line WL2 may be disposed on the second channel pattern AP2. The first word line WL1 and the second word line WL2 may be disposed inside the channel trench CH_T.

Each of the first word lines WL1 and the second word lines WL2 may extend in the first direction DR1. The first word line WL1 and the second word line WL2 may be alternately arranged in the second direction DR2. The first word line WL1 is spaced apart from the second word line WL2 in the second direction DR2.

The first word line WL1 and the second word line WL2 are spaced apart from the bit line BL in the third direction DR3. The first word line WL1 and the second word line WL2 intersect the bit line BL. The first word line WL1 and the second word line WL2 are spaced apart from the contact pattern BC in the third direction DR3.

Each of the first word line WL1 and the second word line WL2 is disposed on the horizontal part AP_H of the channel pattern. The first word line WL1 and the second word line WL2 are disposed between the vertical part AP_V of the channel pattern of the first channel pattern AP1 and the vertical part AP_V of the channel pattern of the second channel pattern AP2.

The first word line WL1 and the second word line WL2 are disposed between the first channel pattern AP1 and the second channel pattern AP2. The first channel pattern AP1 is closer to the first word line WL1 than the second word line WL2. The second channel pattern AP2 is closer to the second word line WL2 than the first word line WL1.

Each of the first word line WL1 and the second word line WL2 may have a width in the second direction DR2. The width of the first word line WL1 at the portion that overlaps the first and second channel patterns AP1 and AP2 in the third direction D3 may differ from the width of the first word line WL1 at the portion that does not overlap the first and second channel patterns AP1 and AP2. The width of the second word line WL2 at the portion that overlaps the first and second channel patterns AP1 and AP2 in the third direction DR3 may be different from the width of the second word line WL2 at the portion that does not overlap the first and second channel patterns AP1 and AP2.

For example, each of the first word line WL1 and the second word line WL2 may include a first portion WLa of the word line, and a second portion WLb of the word line. A width of the first portion WLa of the word line in the second direction DR2 may be smaller than a width of the second portion WLb of the word line in the second direction DR2. As an example, the first portion WLa of the word line may be disposed on the first channel pattern AP1 and the second channel pattern AP2.

Each of the first word line WL1 and the second word line WL2 may include a first portion WLa of the word line and a second portion WLb of the word line that are alternately arranged along the first direction DR1. In the first word line WL1, each first channel pattern AP1 may be disposed between the second portions WLb of the word lines adjacent to each other in the first direction DR1. In the second word line WL2, each second channel pattern AP2 may be disposed between the second portions WLb of the word lines adjacent to each other in the first direction DR1.

However, in some example embodiments, the width of the first portion WLa of the word line in the second direction DR2 may be equal to the width of the second portion WLb of the word line in the second direction DR2. In such a case, a gate insulating film GOX to be described below may fill the space between the first channel patterns AP1 adjacent to each other in the first direction DR1, and the space between the second channel patterns AP2 adjacent to each other in the first direction DR1.

The first channel pattern AP1 and the second channel pattern AP2 are not disposed below the second portions WLb of the word line. A height of the first portion WLa of the word line is smaller than a height of the second portion WLb of the word line. For example, a height difference between the first portion WLa of the word line and the second portion WLb of the word line may be equal to the thickness of the first and second channel patterns AP1 and AP2.

The first word line WL1 and the second word line WL2 include a conductive material, and may include at least one of, for example, a doped polysilicon, a conductive metal nitride, a conductive metal silicon nitride, a metal carbonitride, a conductive metal silicide, a conductive metal oxide, a two-dimensional material, a metal, and a metal alloy.

Each of the first word line WL1 and the second word line WL2 may include an upper face WL_US and a bottom face that are opposite to each other in the third direction DR3. The bottom face of the first word line WL1 and the bottom face of the second word line WL2 face the second face BC_S2 of the contact pattern.

In FIG. 5, the upper faces WL_US of the first and second word lines WL1 and WL2 may be a plane. However, in some example embodiments, as an example, the upper faces WL_US of the first and second word lines WL1 and WL2 may be rounded in a convex shape. In some example embodiments, the upper faces WL_US of the first and second word lines WL1 and WL2 may be rounded in a concave shape.

The following description will be given from the viewpoint of a cross-sectional view such as those in FIGS. 3 and 5. On the basis of the second face BC_S2 of the contact pattern, the upper face WL_US of the first and second word lines WL1 and WL2 may be higher than or equal to the uppermost part AP_UUS of the first and second channel patterns AP1 and AP2. A height H1 from the second face BC_S2 of the contact pattern to the uppermost part AP_UUS of the first and second channel patterns AP1 and AP2 may be smaller than or equal to a height H2 from the second face BC_S2 of the contact pattern to the uppermost part WL_US of the first and second word lines WL1 and WL2.

On the basis of the second face BC_S2 of the contact pattern, the uppermost part AP_UUS of the first and second channel patterns AP1 and AP2 is lower than the second face 175_S2 of the channel insulating film. The height H1 from the second face BC_S2 of the contact pattern to the uppermost part AP_UUS of the first and second channel patterns AP1 and AP2 is smaller than a height H3 from the second face BC_S2 of the contact pattern to the second face 175_S2 of the channel insulating film.

The gate insulating film GOX may be disposed between the first word line WL1 and the first channel pattern AP1, and between the second word line WL2 and the second channel pattern AP2. The gate insulating film GOX may extend in the first direction DR1 alongside the first word line WL1 and the second word line WL2.

The gate insulating film GOX may extend along the vertical part AP_V of the channel pattern. From the viewpoint of a cross-sectional view, the gate insulating film GOX between the first word line WL1 and the first channel pattern AP1 may be separated from the gate insulating film GOX between the second word line WL2 and the second channel pattern AP2.

The gate insulating film GOX may include a silicon oxide film, a silicon oxynitride film, a high dielectric constant insulating film having a higher dielectric constant than the silicon oxide film, or a combination thereof. For example, the gate insulating film GOX may include, but not limited to, aluminum oxide.

A part of the gate insulating film GOX may protrude in the third direction DR3 beyond the upper face WL_US of the first and second word lines WL1 and WL2. A part of the gate insulating film GOX may protrude in the third direction DR3 beyond the uppermost part AP_UUS of the first and second channel patterns AP1 and AP2.

A height from the second face BC_S2 of the contact pattern to the uppermost part GOX_UUS of the gate insulating film may be greater than a height H1 from the second face BC_S2 of the contact pattern to the uppermost part AP_UUS of the first and second channel patterns AP1 and AP2. The height from the second face BC_S2 of the contact pattern to the uppermost part GOX_UUS of the gate insulating film may be greater than the height H2 from the second face BC_S2 of the contact pattern to the upper face WL_US of the word lines WL1 and WL2.

The height from the second face BC_S2 of the contact pattern to the uppermost part GOX_UUS of the gate insulating film is shown as being the same or substantially the same as the height H3 from the second face BC_S2 of the contact pattern to the second face 175_S2 of the channel insulating film, but the inventive concepts are not limited thereto.

The gate separation pattern GSS may be disposed between the first word line WL1 and the second word line WL2 that are adjacent to each other in the second direction DR2. The first word line WL1 and the second word line WL2 may be separated by the gate separation pattern GSS. The gate separation pattern GSS may extend in the first direction DR1 between the first word line WL1 and the second word line WL2.

The first word line WL1 may be disposed between the gate separation pattern GSS and the first channel pattern AP1. The second word line WL2 may be disposed between the gate separation pattern GSS and the second channel pattern AP2.

The gate separation pattern GSS may be made of an insulating material. Although the gate separation pattern GSS is shown as being a single film, this is only for convenience of explanation, and the inventive concepts are not limited thereto.

The bit line BL may be disposed on the first channel pattern AP1 and the second channel pattern AP2. The bit line BL may be connected to the first channel pattern AP1 and the second channel pattern AP2. The bit line BL may be connected to the vertical part AP_V of the channel pattern of the first channel pattern AP1. The bit line BL may be connected to the vertical part AP_V of the channel pattern of the second channel pattern AP2.

The bit line BL may extend long in the second direction DR2. Adjacent bit lines BL may be spaced apart from each other in the first direction DR1.

The bit line BL may include an extension BLe and a protrusion BLp. The extension BLe of the bit line may extend in the second direction DR2. In the semiconductor memory device according to some example embodiments, the width of the extension BLe of the bit line in the first direction DR1 may decrease, as it goes away from the channel insulating film 175 and the gate separation pattern GSS. For example, the extension BLe of the bit line may be formed by a subtractive etching process.

The protrusion BLp of the bit line may protrude in the third direction DR3. The protrusion BLp of the bit line may protrude from the extension BLe of the bit line toward the first channel pattern AP1. The protrusion BLp of the bit line may protrude from the extension BLe of the bit line toward the second channel pattern APL.

The protrusion BLp of the bit line may be connected to the first channel pattern AP1 and the second channel pattern AP2. The protrusion BLp of the bit line may connect the first channel pattern AP1 and the extension BLe of the bit line. The protrusion BLp of the bit line may connect the second channel pattern AP2 and the extension BLe of the bit line. The protrusion BLp of the bit line may include the lowermost part of the bit line BL on the basis of the second face BC_S2 of the contact pattern.

The bit line BL may include at least one of, for example, a doped semiconductor material, a conductive metal nitride, a conductive metal silicon nitride, a metal carbonitride, a conductive metal silicide, a conductive metal oxide, a two-dimensional material, and/or a metal. Although the bit line BL is shown as being a single film, this is only for convenience of explanation, and is the inventive concepts are not limited thereto.

In the cross-sectional views such as FIGS. 3 and 5, the height H1 from the second face BC_S2 of the contact pattern to the uppermost part AP_UUS of the first and second channel patterns AP1 and AP2 may be equal to the height from the second face BC_S2 of the contact pattern to the lowermost part of the bit line BL. The height H1 from the second face BC_S2 of the contact pattern to the lowermost part of the bit line BL may be smaller than the height H3 from the second face BC_S2 of the contact pattern to the second face 175_S2 of the channel insulating film.

The extension BLe of the bit line may be disposed inside the second interlayer insulating film 264. The third interlayer insulating film 265 may be disposed on the bit line BL and the second interlayer insulating film 265. The second interlayer insulating film 264 and the third interlayer insulating film 265 may each include an insulating material.

The capacitor structure DSP may be disposed between the peri-gate structure PG and the bit line BL. A bonding pad may not be disposed between the capacitor structure DSP and the peri-gate structure PG. In the semiconductor memory device according to some example embodiments, the bit line BL, the first word line WL1, and the second word line WL2 may not be connected to the peri-connecting wiring 243 through a bonding pad.

Unlike that shown in FIG. 2, the first channel pattern AP1 and/or the second channel pattern AP2 disposed at the boundary portion between the cell array region CAR and the peripheral circuit region PCR may not be connected to the first capacitor electrode 251. That is, the first capacitor electrode 251 may not be disposed at the boundary portion between the cell array region CAR and the peripheral circuit region PCR.

The first word line WL1 and/or the second word line WL2 disposed at the boundary portion between the cell array region CAR and the peripheral circuit region PCR may be, but not limited to, dummy word lines that are not used for the operation of the memory cells.

The first channel pattern AP1 and/or the second channel pattern AP2 disposed at the boundary portion between the cell array region CAR and the peripheral circuit region PCR may be, but not limited to, dummy channel patterns that are not used for the operation of the memory cells.

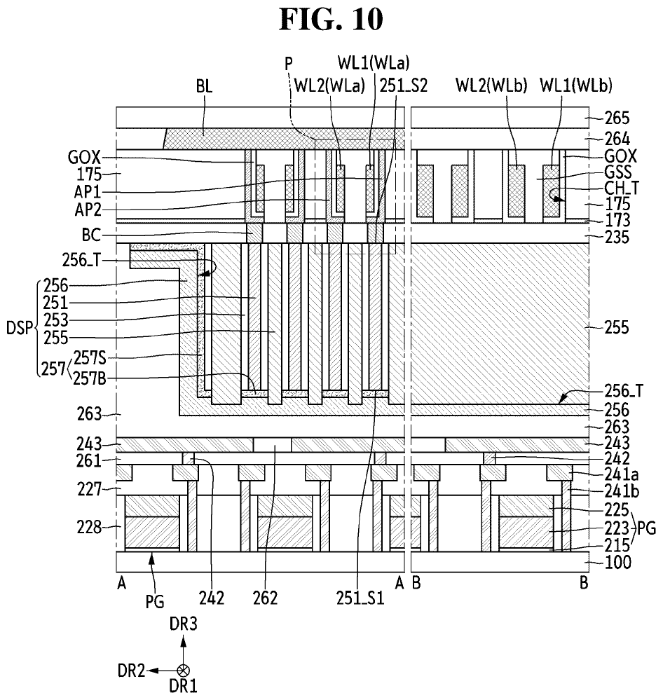

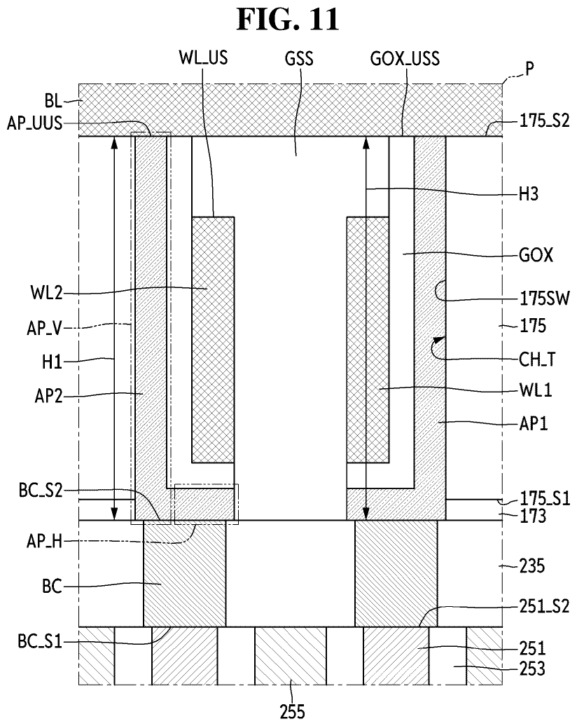

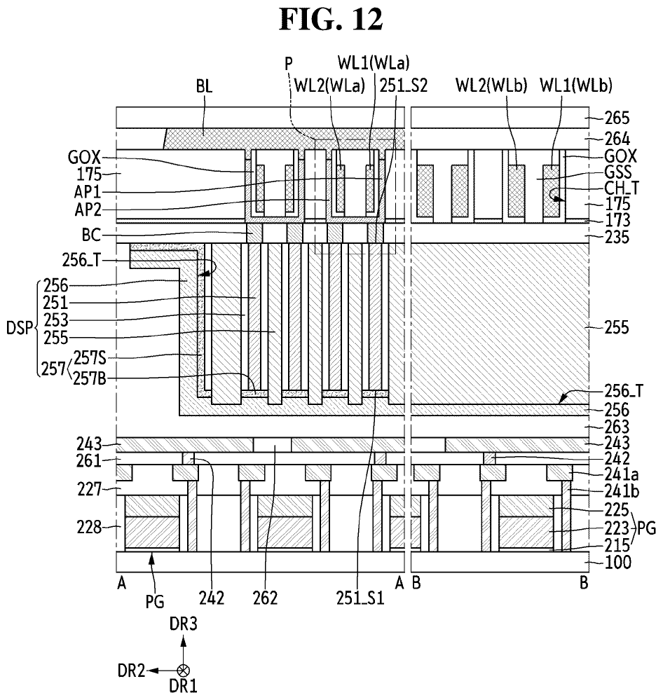

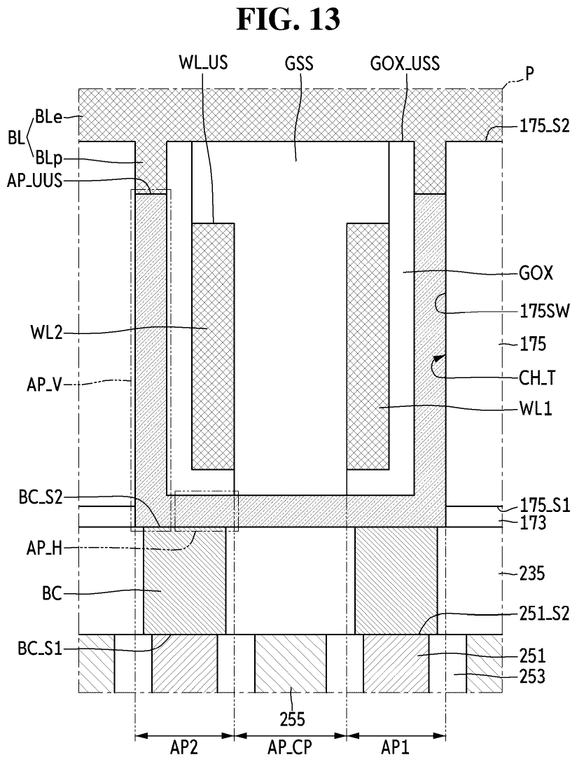

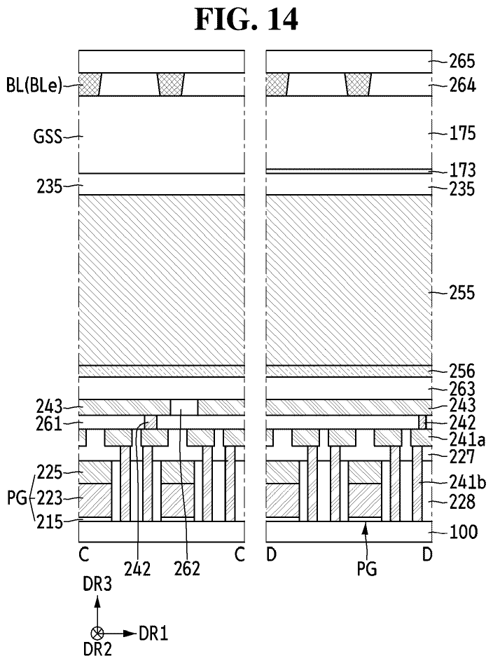

FIGS. 10 and 11 are diagrams for explaining a semiconductor memory device according to some example embodiments. FIGS. 12 and 13 are diagrams for explaining a semiconductor memory device according to some example embodiments. FIG. 14 is a diagram for explaining a semiconductor memory device according to some example embodiments. For convenience of explanation, differences from those explained using FIGS. 1 to 9 will be mainly explained.

For reference, FIGS. 11 and 13 are enlarged views of a portion P of FIGS. 10 and 12, respectively.

Referring to FIGS. 10 and 11, in the semiconductor memory device according to some example embodiments, the height H1 from the second face BC_S2 of the contact pattern to the uppermost part AP_UUS of the first and second channel patterns AP1 and AP2 may be equal to the height H3 from the second face BC_S2 of the contact pattern to the second face 175_S2 of the channel insulating film.

The height H1 from the second face BC_S2 of the contact pattern to the uppermost part AP_UUS of the first and second channel patterns AP1 and AP2 may be equal to the height from the second face BC_S2 of the contact pattern to the uppermost part GOX_UUS of the gate insulating film.

The height H1 from the second face BC_S2 of the contact pattern to the uppermost part AP_UUS of the first and second channel patterns AP1 and AP2 may be greater than the height from the second face BC_S2 of the contact pattern to the upper face WL_US of the first and second word lines WL1 and WL2.

For example, the bit line BL may include an extension of the bit line (BLe of FIG. 5) extending in the second direction DR2, but may not include an extension of the bit line (BLp of FIG. 5) protruding in the third direction DR3.

Referring to FIGS. 12 and 13, in the semiconductor memory device according to some example embodiments, the first channel pattern AP1 and the second channel pattern AP2 may be connected by a connecting channel pattern AP_CP.

The connecting channel pattern AP_CP may include the same or substantially the same material as the first channel pattern AP1 and the second channel pattern AP2. The connected shape of the first channel pattern AP1, the second channel pattern AP2, and the connecting channel pattern AP_CP may have a “U” shape when viewed in a cross-section.

The first channel pattern AP1, the second channel pattern AP2, and the connecting channel pattern AP_CP may be distinguished on the basis of the first word line WL1 and the second word line WL2. In FIG. 13, the first word line WL1 will be explained as an example. The first word line WL1 may include an inner wall that faces the side wall 175SW of the channel insulating film, and an outer wall that is opposite to the inner wall in the second direction DR2. A boundary between the first channel pattern AP1 and the connecting channel pattern AP_CP may be an extension line of the outer wall of the first word line WL1 extending in the third direction DR3.

From the viewpoint of a cross-sectional view, the gate insulating film GOX between the first word line WL1 and the first channel pattern AP1 is shown as being separated from the gate insulating film GOX between the second word line WL2 and the second channel pattern AP2, but the inventive concepts are not limited thereto. However, in some example embodiments, the gate insulating film GOX between the first word line WL1 and the first channel pattern AP1 may be connected to the gate insulating film GOX between the second word line WL2 and the second channel pattern AP2.

Referring to FIG. 14, in the semiconductor memory device according to some example embodiments, the width of the extension BLe of the bit line in the first direction DR1 may increase, as it goes away from the channel insulating film 175 and the gate separation pattern GSS.

For example, the extension BLe of the bit line may be formed through a damascene process.

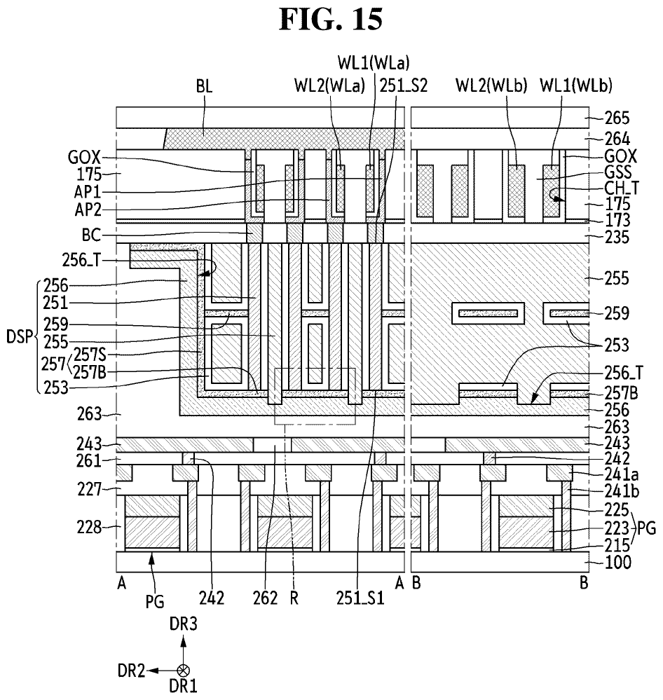

FIGS. 15 to 18 are diagrams for explaining a semiconductor memory device according to some example embodiments. For convenience of explanation, differences from the contents explained using FIGS. 1 to 9 will be mainly explained.

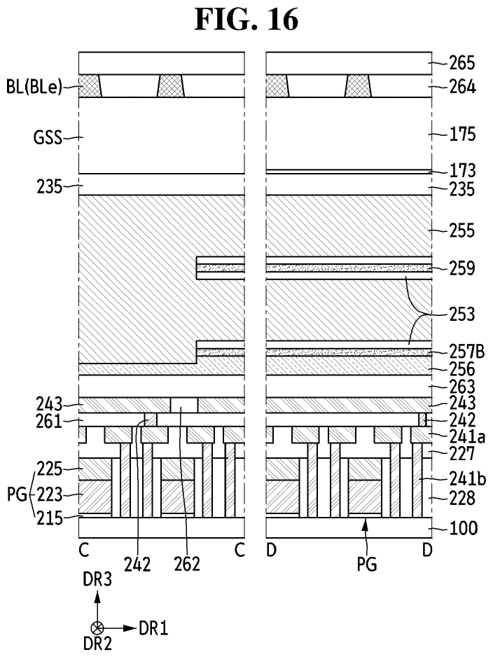

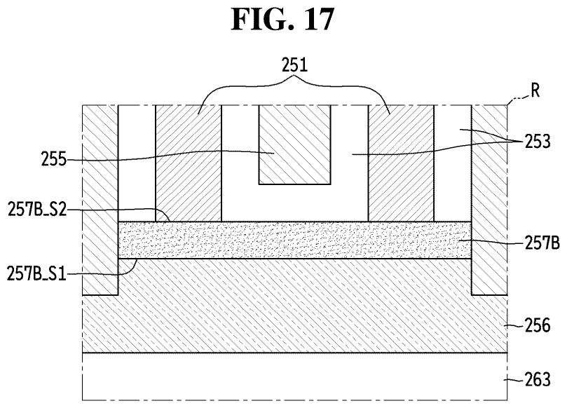

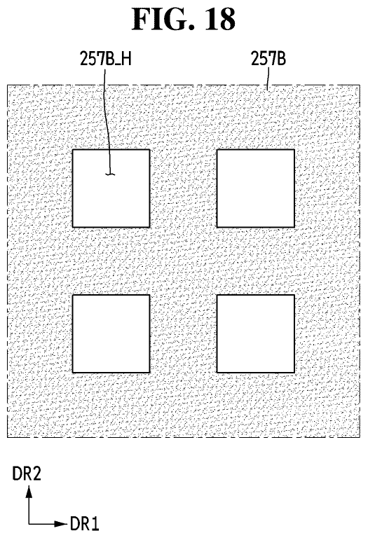

For reference, FIG. 15 is a cross-sectional view taken along A-A and B-B of FIG. 2. FIG. 16 is a cross-sectional view taken along C-C and D-D of FIG. 2. FIG. 17 is an enlarged view of a portion R of FIG. 15. FIG. 18 is a diagram showing the shape of the bottom part of the first electrode mold insulating pattern in the capacitor structure of FIG. 15.

Referring to FIGS. 15 to 18, in the semiconductor memory device according to some example embodiments, the capacitor structure DSP may further include an electrode support 259.

The electrode support 259 may be spaced apart from the bottom part 257B of the first electrode mold insulating pattern in the third direction DR3. The electrode support 259 may come into contact with a side wall of the first capacitor electrode 251.

The shape of the bottom part 257B of the first electrode mold insulating pattern may also change, as the capacitor structure DSP includes the electrode support 259. The bottom part 257B of the first electrode mold insulating pattern may have a plate shape.

The bottom part 257B of the first electrode mold insulating pattern may include a plurality of first mold insulating holes 257B_H. The first mold insulating hole 257B_H may extend from a first face 257B_S1 of the bottom part of the first electrode mold insulating pattern to a second face 257B_S2 of the bottom part of the first electrode mold insulating pattern. The first mold insulating hole 257B_H may expose the plate electrode 256.

The second capacitor electrode 255 passes through the first mold insulating hole 257B_H, and may be connected to the plate electrode 256. The second capacitor electrode 255 may penetrate the bottom part 257B of the first electrode mold insulating pattern.

The electrode support 259 may have a shape corresponding to the bottom part 257B of the first electrode mold insulating pattern. The electrode support 259 may include an electrode support hole. The electrode support hole may be disposed at a position corresponding to the first mold insulating hole 257B_H.

The capacitor dielectric film 253 may extend along the upper face and the bottom face of the electrode support 259. The upper face of the electrode support table 259 may be opposite to the bottom face of the electrode support table 259 in the third direction DR3.

The electrode support 259 may include at least one of a silicon nitride, a silicon carbonitride, a silicon boron nitride, a silicon oxycarbide, a silicon oxynitride, a silicon oxide, and/or a silicon oxycarbonitride.

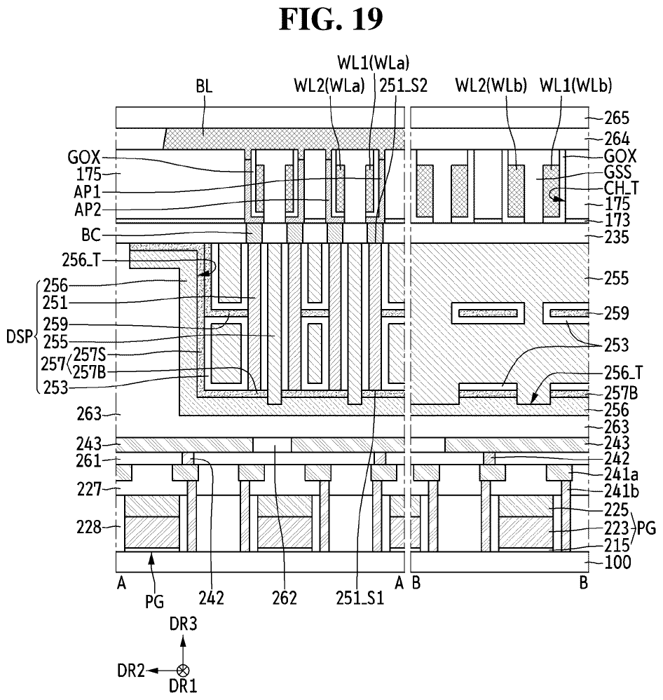

FIG. 19 is a diagram for explaining a semiconductor memory device according to some example embodiments. For convenience of explanation, differences from those explained using FIGS. 15 to 18 will be mainly explained.

Referring to FIG. 19, in the semiconductor memory device according to some example embodiments, a part of the electrode support 259 may extend along a profile of the side wall part 257S of the first electrode mold insulating pattern.

The side wall part 257S of the first electrode mold insulating pattern may include a first region and a second region. The first region of the side wall part 257S of the first electrode mold insulating pattern may be located between the electrode support 259 and the bottom part 257B of the first electrode mold insulating pattern. The second region of the side wall part 257S of the first electrode mold insulating pattern may be located between the electrode support 259 and the contact separation insulating film 235.

The electrode support 259 may extend along a profile of the second region of the side wall part 257S of the first electrode mold insulating pattern. The electrode support 259 is not disposed on the first region of the side wall part 257S of the first electrode mold insulating pattern.

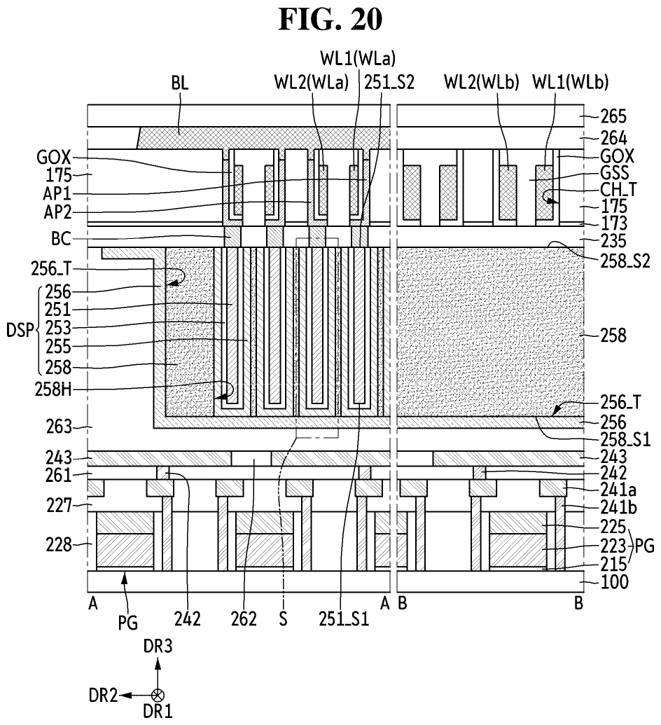

FIGS. 20 to 23 are diagrams for explaining a semiconductor memory device according to some example embodiments. For convenience of explanation, differences from those explained using FIGS. 1 to 9 will be mainly explained.

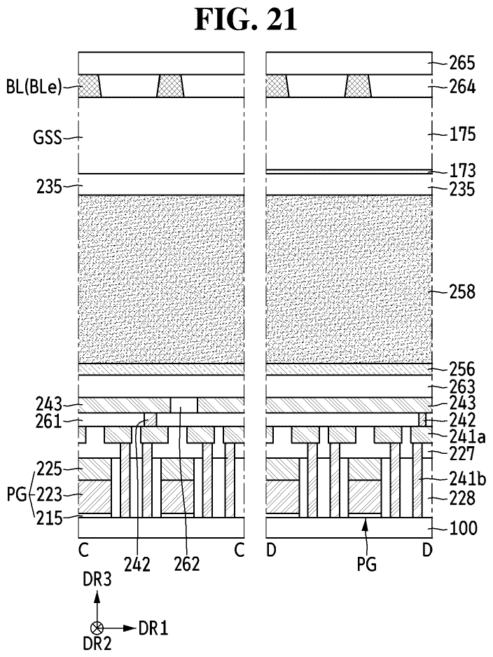

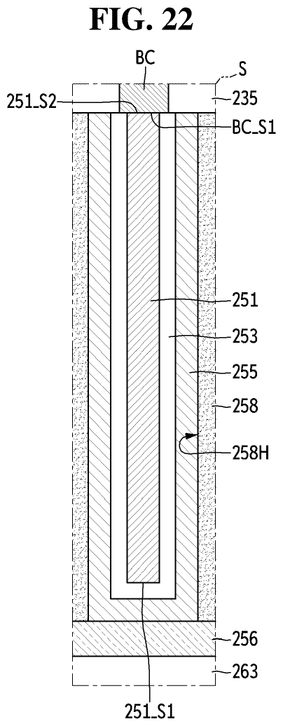

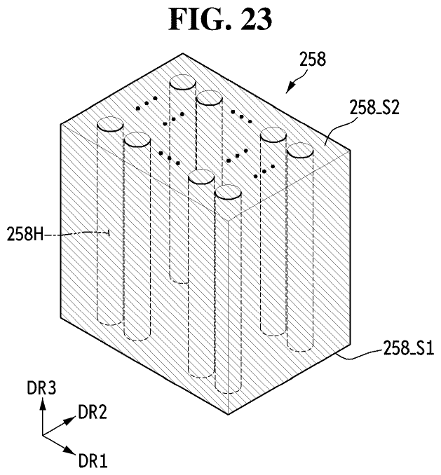

For reference, FIG. 20 is a cross-sectional view taken along A-A and B-B of FIG. 2. FIG. 21 is a cross-sectional view taken along C-C and D-D of FIG. 2. FIG. 22 is an enlarged view of a portion S of FIG. 20. FIG. 23 is a diagram for explaining the shape of the second electrode mold insulating pattern in the capacitor structure of FIG. 20.

Referring to FIGS. 20 to 23, in the semiconductor memory device according to some example embodiments, the capacitor structure DSP may include a first capacitor electrode 251, a capacitor dielectric film 253, a second capacitor electrode 255, a plate electrode 256, and a second electrode mold insulating pattern 258.

The second electrode mold insulating pattern 258 may be disposed on the plate electrode 256. The second electrode mold insulating pattern 258 may come into contact with the plate electrode 256. The second electrode mold insulating pattern 258 may fill the electrode mold trench 256_T.

The second electrode mold insulating pattern 258 may include a first face 258_S1 and a second face 258_S2 that are opposite to each other in the third direction DR3. The first face 258_S1 of the second electrode mold insulating pattern may face the peri-gate structure PG. The first face 258_S1 of the second electrode mold insulating pattern may come into contact with the plate electrode 256. The second face 258_S2 of the second electrode mold insulating pattern may face the first channel pattern AP1 and the second channel pattern AP2.

The second electrode mold insulating pattern 258 may include a plurality of second mold insulating holes 258H. The second mold insulating hole 258H may penetrate the second electrode mold insulating pattern 258 in the third direction DR3. The second mold insulating hole 258H may extend from the first face 258_S1 of the second electrode mold insulating pattern to the second face 258_S2 of the second electrode mold insulating pattern. The bottom face of the second mold insulating hole 258H may be defined by the plate electrode 256.

The second electrode mold insulating pattern 258 may include an insulating material. The second electrode mold insulating pattern 258 may include, but not limited to, at least one of a silicon oxide, a silicon nitride, a silicon oxynitride, a silicon carbonitride, a silicon oxycarbide, and/or a silicon oxycarbonitride.

The second capacitor electrode 255 may extend along the side wall and bottom face of the second mold insulating hole 258H. The second capacitor electrode 255 may be connected to the plate electrode 256.

The capacitor dielectric film 253 may be disposed on the second capacitor electrode 255. The capacitor dielectric film 253 may extend along the side wall and bottom face of the second mold insulating hole 258H.

For example, the second capacitor electrode 255 and the capacitor dielectric film 253 may not be disposed on the second face 258_S2 of the second electrode mold insulating pattern. The second capacitor electrode 255 and the capacitor dielectric film 253 may not cover the second face 258_S2 of the second electrode mold insulating pattern.

The first capacitor electrode 251 may be disposed on the capacitor dielectric film 253. The first capacitor electrode 251 may fill the second mold insulating hole 258H.

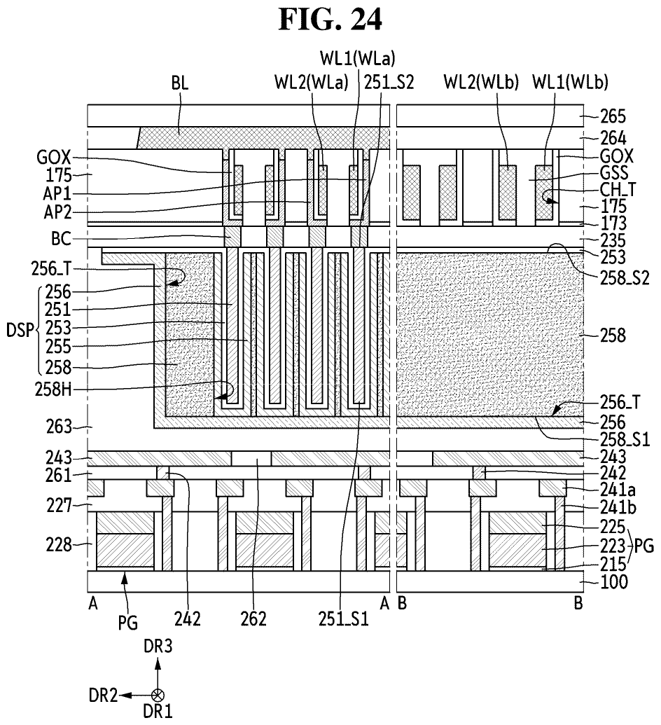

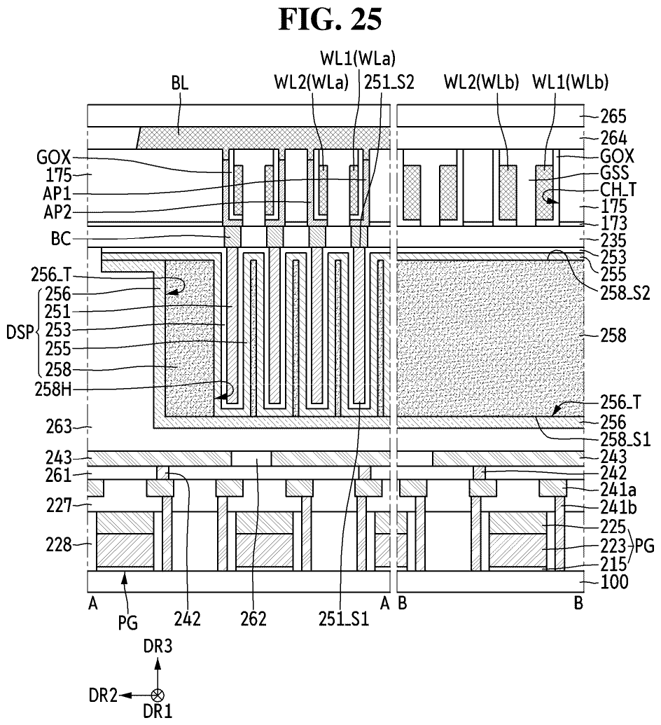

FIGS. 24 and 25 are diagrams for explaining a semiconductor memory device according to some example embodiments. For convenience of explanation, differences from those explained using FIGS. 20 to 23 will be mainly explained.

Referring to FIGS. 24 and 25, in the semiconductor memory device according to some example embodiments, the capacitor dielectric film 253 may be disposed on the second face 258_S2 of the second electrode mold insulating pattern.

The capacitor dielectric film 253 may cover the second face 258_S2 of the second electrode mold insulating pattern. The capacitor dielectric film 253 may extend along the second face 258_S2 of the second electrode mold insulating pattern.

In FIG. 24, the capacitor dielectric film 253 may come into contact with the second face 258_S2 of the second electrode mold insulating pattern.

In FIG. 25, the second capacitor electrode 255 may cover the second face 258_S2 of the second electrode mold insulating pattern. The second capacitor electrode 255 may extend along the second face 258_S2 of the second electrode mold insulating pattern. The second capacitor electrode 255 and the capacitor dielectric film 253 may be sequentially disposed on the second face 258_S2 of the second electrode mold insulating pattern. For example, the second capacitor electrode 255 may come into contact with the second face 258_S2 of the second electrode mold insulating pattern.

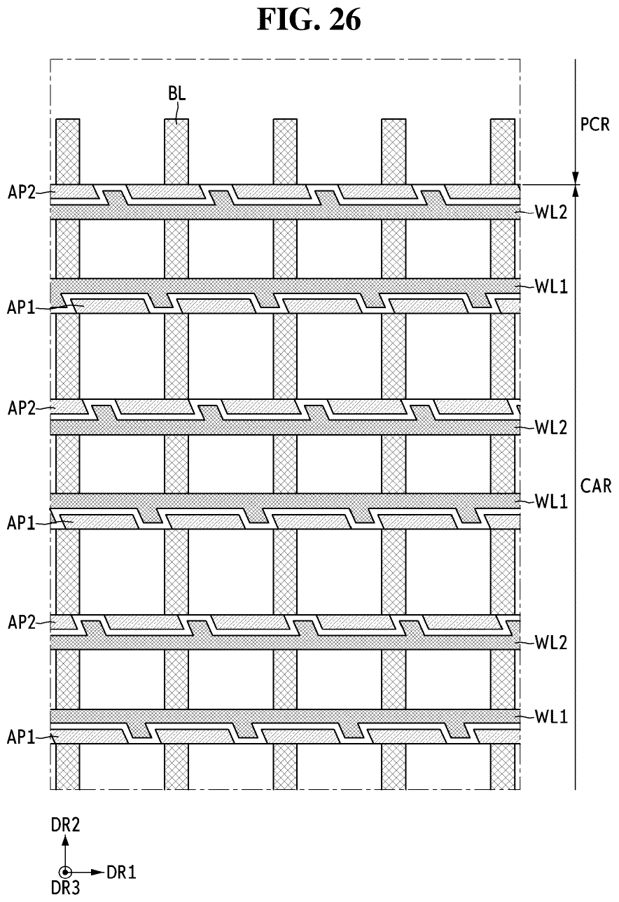

FIGS. 26 to 29 are diagrams for explaining a semiconductor memory device according to some example embodiments, respectively. For convenience of explanation, differences from those explained using FIGS. 1 to 9 will be mainly explained.

Referring to FIG. 26, in the semiconductor memory device according to some example embodiments, the first channel pattern AP1 and the second channel pattern AP2 may be arranged alternately in a diagonal direction with respect to the first direction DR1 and the second direction DR2. Here, the diagonal direction may be parallel to the upper face of the substrate (100 of FIG. 3).

The first channel pattern AP1 and the second channel pattern AP2 may be formed to be twisted in the diagonal direction. From a planar viewpoint, the first channel pattern AP1 and the second channel pattern AP2 may each have a parallelogram shape or a rhombus shape.

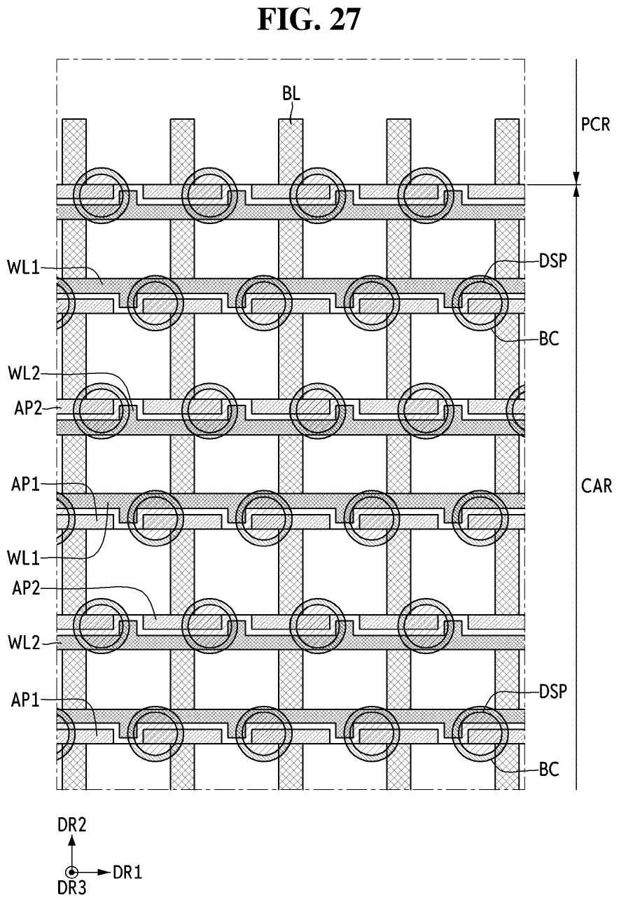

Referring to FIG. 27, in the semiconductor memory device according to some example embodiments, the contact patterns BC and the capacitor structures DSP may be arranged in a zigzag shape or a honeycomb shape from a planar viewpoint.

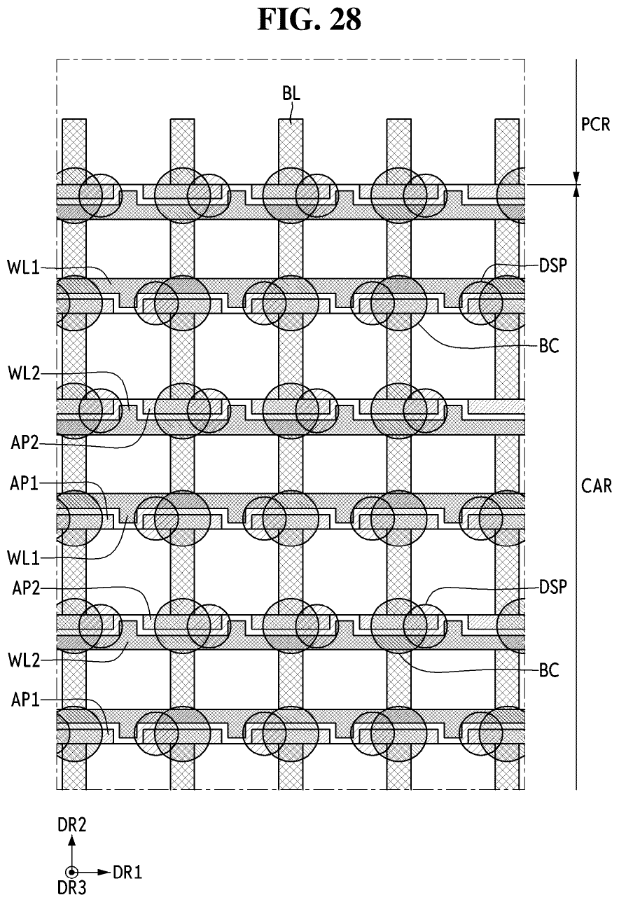

Referring to FIG. 28, in the semiconductor memory device according to some example embodiments, the capacitor structures DSP may be arranged to be offset from the contact pattern BC from a planar viewpoint. That is, a center of the capacitor structures DSP may be offset from a center of the contact pattern BC and there may be a vertical overlap between the capacitor structures DSP and the contact pattern BC.

Each capacitor structure DSP may come into contact with a part of the contact pattern BC.

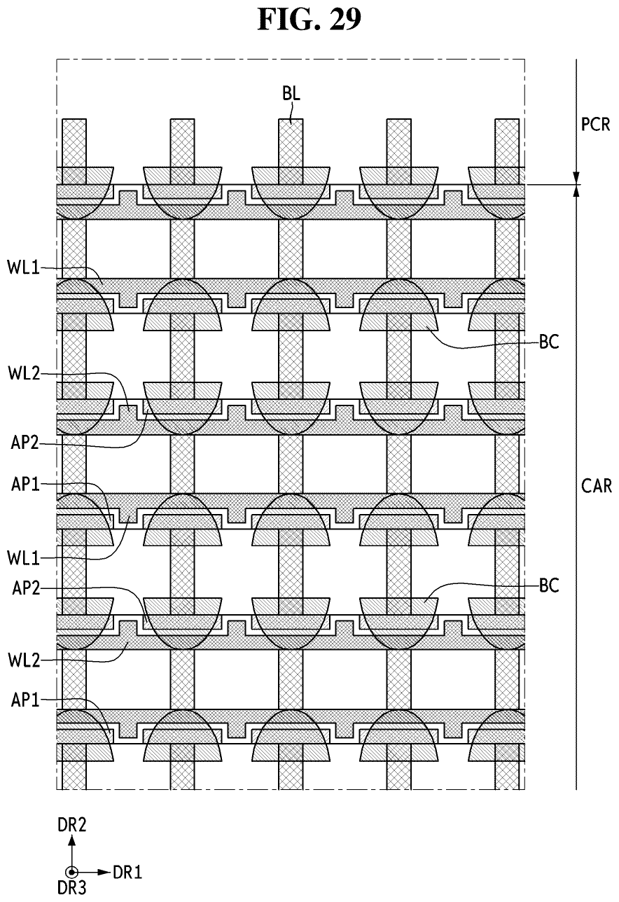

Referring to FIG. 29, in the semiconductor memory device according to some example embodiments, each of the contact patterns BC arranged on the first channel pattern AP1 and the second channel pattern AP2 may have a semicircular shape or a semi-elliptical shape from a planar viewpoint.

The contact patterns BC may be disposed symmetrically with each other from a planar viewpoint.

FIGS. 30 to 37 are intermediate stage diagrams for explaining a method for fabricating a semiconductor memory device according to some example embodiments.

Referring to FIG. 30, the peri-gate structure PG may be formed on the substrate 100.

The peri-wiring line 241a and the peri-contact plug 241b may be formed on the substrate 100. The peri-connecting wiring 243 and the peri-connecting via 242 may be formed on the peri-wiring line 241a.

The first interlayer insulating film 263 may be formed on the peri-connecting wiring 243.

Next, a capacitor trench DSP_T may be formed inside the first interlayer insulating film 263. The capacitor trench DSP_T may be formed in a cell array region (CAR of FIG. 1) of the substrate 100.

The plate electrode 256 may be formed on the first interlayer insulating film 263. The plate electrode 256 may be formed along the side walls and bottom face of the capacitor trench DSP_T. The plate electrode 256 may extend along the upper face of the first interlayer insulating film 263. The plate electrode 256 may define an electrode mold trench 256_T.

The first electrode mold insulating pattern 257 may be formed on the plate electrode 256. The first electrode mold insulating pattern 257 may be formed along the profile of the plate electrode 256. The first electrode mold insulating pattern 257 may be formed along the side walls and bottom face of the electrode mold trench 256_T.

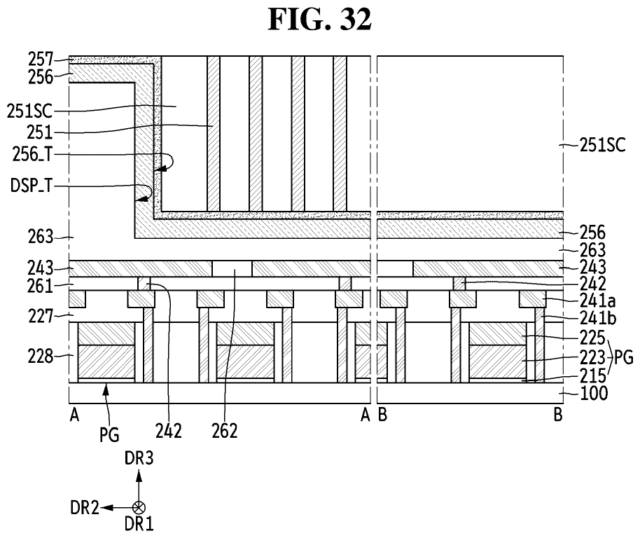

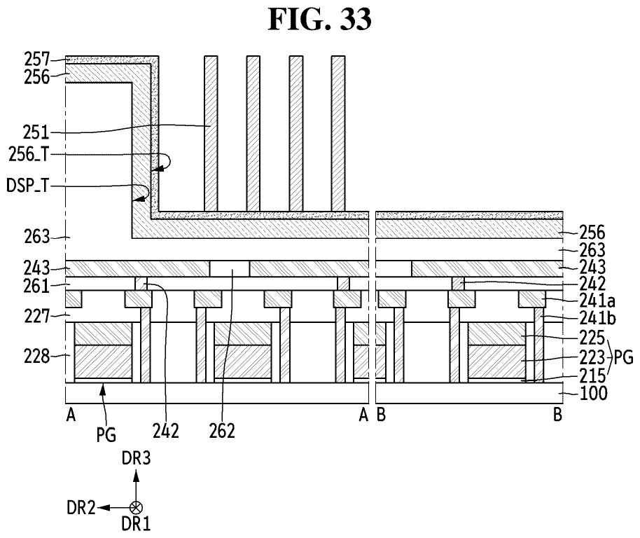

A mold sacrificial pattern 251SC may be formed on the first electrode mold insulating pattern 257. The mold sacrificial pattern 251SC may fill the electrode mold trench 256_T. The mold sacrificial pattern 251SC may include a material having an etching selectivity with respect to the first electrode mold insulating pattern 257. Furthermore, the mold sacrificial pattern 251SC may include a material having an etching selectivity with respect to the first capacitor electrode (251 of FIGS. 32 and 33).

However, in some example embodiments, an electrode support film may be formed inside the electrode mold trench 256_T. The electrode support film may be formed inside the mold sacrificial pattern 251SC. The electrode support film may then be the electrode support (259 of FIG. 15).

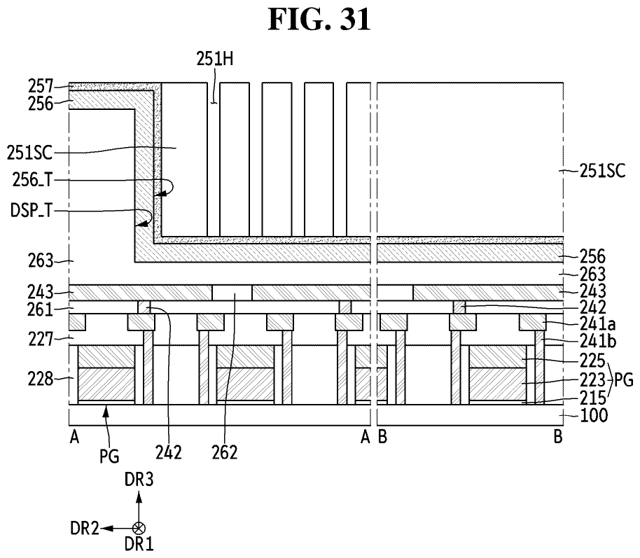

Referring to FIG. 31, a first capacitor electrode hole 251H may be formed inside the mold sacrificial pattern 251SC.

The first capacitor electrode hole 251H may penetrate the mold sacrificial pattern 251SC. The first capacitor electrode hole 251H may expose the first electrode mold insulating pattern 257.

The first capacitor electrode hole 251H may extend in the third direction DR3. The first capacitor electrode hole 251H may have a cylindrical shape.

Referring to FIGS. 31 and 32, the first capacitor electrode 251 may be formed inside the first capacitor electrode hole 251H.

The first capacitor electrode 251 may fill the first capacitor electrode hole 251H. For example, the first capacitor electrode 251 may come into contact with the first electrode mold insulating pattern 257.

Referring to FIGS. 32 and 33, the mold sacrificial pattern 251SC inside the electrode mold trench 256_T may be removed.

The mold sacrificial pattern 251SC may be removed to expose a side wall of the first capacitor electrode 251.

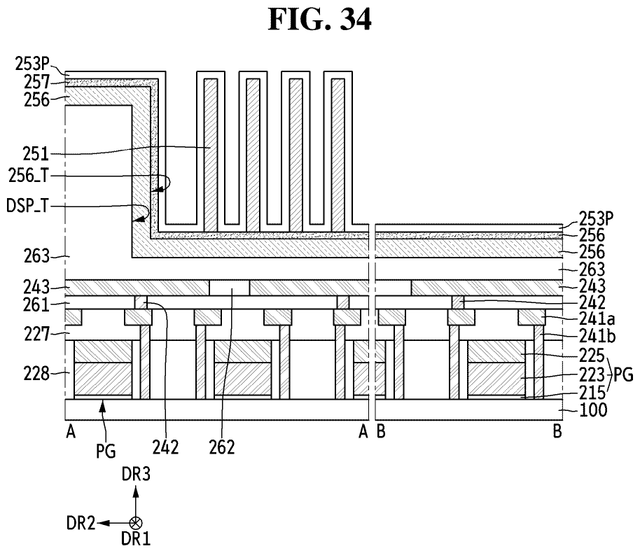

Referring to FIG. 34, a pre-capacitor dielectric film 253P may be formed along the side wall and upper face (251_S2 of FIG. 3) of the first capacitor electrode 251.

The pre-capacitor dielectric film 253P may be formed along the profile of the first electrode mold insulating pattern 257.

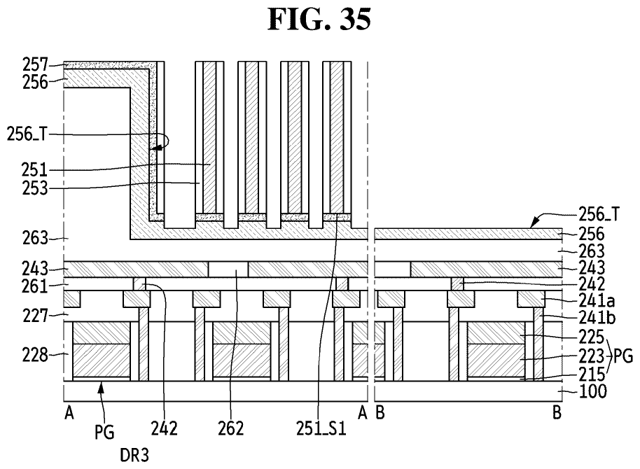

Referring to FIGS. 34 and 35, the pre-capacitor dielectric film 253P may be anisotropically etched to form the capacitor dielectric film 253 on the side wall of the first capacitor electrode 251.

The pre-capacitor dielectric film 253P formed on the upper face of the first capacitor electrode 251 may be removed, while the capacitor dielectric film 253 is being formed. In addition, the pre-capacitor dielectric film 253P formed on the bottom face of the electrode mold trench 256_T may also be removed.

In addition, the first electrode mold insulating pattern 257 formed on the bottom face of the electrode mold trench 256_T may be patterned, while the capacitor dielectric film 253 is being formed. As a result, the sub-electrode insulating pattern (257B_SP of FIG. 9) may be formed.

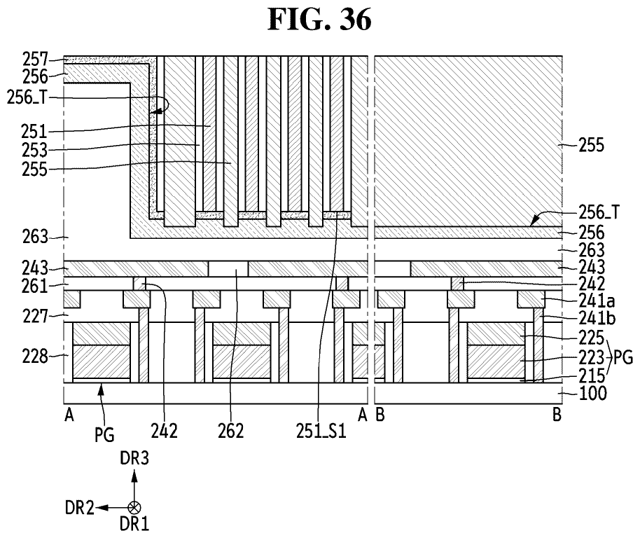

Referring to FIGS. 35 and 36, the second capacitor electrode 255 may be formed on the capacitor dielectric film 253.

The second capacitor electrode 255 may fill the electrode mold trench 256_T that remains after the capacitor dielectric film 253 and the first capacitor electrode 251 are formed.

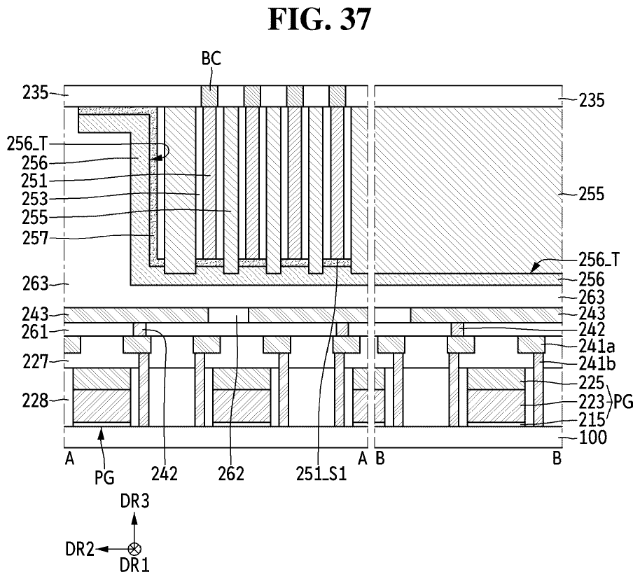

Referring to FIG. 37, the plate electrode 256 and the first electrode mold insulating pattern 257 disposed on the peripheral circuit region (PCR of FIG. 1) of the substrate 100 may be removed.

Next, a first interlayer insulating film 263 may be additionally formed so that the upper face of the first interlayer insulating film 263 is disposed on the same or substantially the same plane as the upper face of the second capacitor electrode 255.

Next, the contact separation insulating film 235 may be formed on the second capacitor electrode 255. The contact patterns BC may be formed inside the contact separation insulating film 235. The contact pattern BC may be connected to the first capacitor electrode 251.

Next, referring to FIG. 3, the first channel pattern AP1, the second channel pattern AP2, the first word line WL1, the second word line WL2, and the bit line BL may be formed on the contact patterns BC.

The temperature for forming the capacitor structure DSP may be higher than the temperature for forming the first channel pattern AP1 and the second channel pattern AP2. When the capacitor structure DSP is formed after forming the first channel pattern AP1 and the second channel pattern AP2, the first channel pattern AP1 and the second channel pattern AP2 may be deteriorated while the capacitor structure DSP is being formed. That is, the characteristics of the first channel pattern AP1 and the second channel pattern AP2 may be degraded. This may result in a degradation in performance and reliability of the semiconductor memory device.

In the method for fabricating the semiconductor memory device according to some example embodiments, the first channel pattern AP1 and the second channel pattern AP2 may be formed after the capacitor structure DSP is formed. The heat treatment process or the like during the formation of the capacitor structure DSP may not affect or may have a reduced effect on the first channel pattern AP1 and the second channel pattern AP2. That is, the first channel pattern AP1 and the second channel pattern AP2 may not be deteriorated or may have reduced deterioration due to the process of forming the capacitor structure DSP. Accordingly, the performance and reliability of the semiconductor memory device can be improved and/or enhanced.

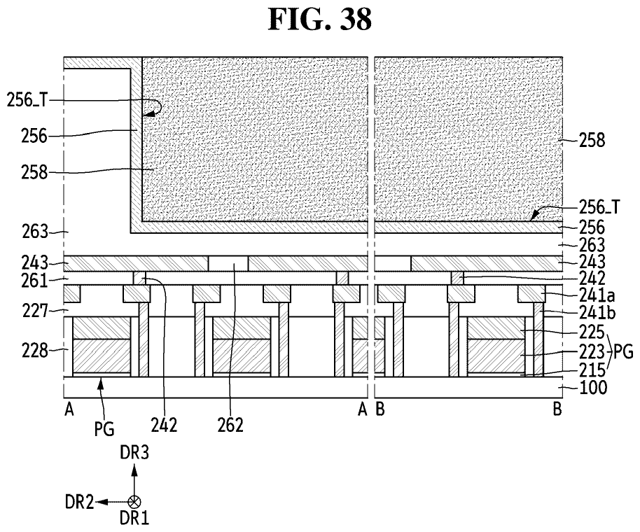

FIGS. 38 to 42 are intermediate stage diagrams for explaining a method for fabricating a semiconductor memory device according to some example embodiments.

For reference, the explanation of FIG. 38 explains the fabricating process after the peri-connecting wiring 243 and the peri-connecting via 242 are formed.

Referring to FIG. 38, the first interlayer insulating film 263 including the capacitor trench DSP_T may be formed on the peri-connecting wiring 243.

The plate electrode 256 may be formed along the side wall and bottom face of the capacitor trench DSP_T.

The second electrode mold insulating pattern 258 may be formed on the plate electrode 256. The second electrode mold insulating pattern 258 may fill the electrode mold trench 256_T. The second electrode mold insulating pattern 258 may come into contact with the plate electrode 256.

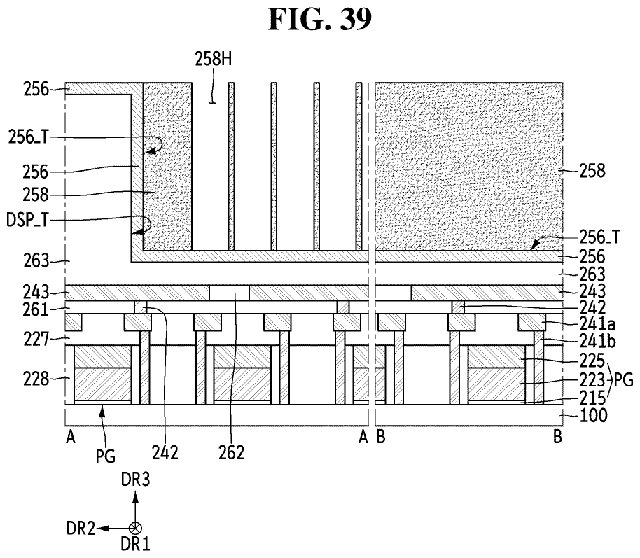

Referring to FIG. 39, a second mold insulating hole 258H may be formed inside the second electrode mold insulating pattern 258.

The second mold insulating hole 258H may penetrate the second electrode mold insulating pattern 258. The second mold insulating hole 258H may expose the plate electrode 256.

The second mold insulating hole 258H may extend in the third direction DR3. The second mold insulating hole 258H may have a cylindrical shape.

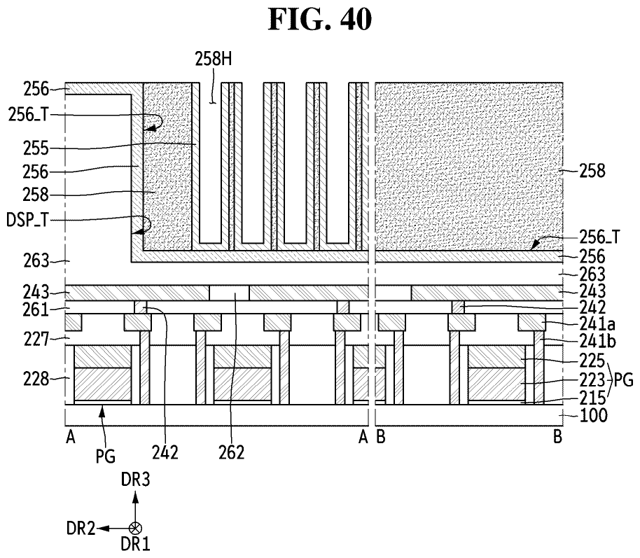

Referring to FIGS. 39 and 40, the second capacitor electrode 255 may be formed along the side wall and bottom face of the second mold insulating hole 258H.

For example, the pre-capacitor electrode may be formed along the side wall and bottom face of the second mold insulating hole 258H. The pre-capacitor electrode may also be formed on the upper face of the second electrode mold insulating pattern 258. A mold pattern may be formed on the pre-capacitor electrode. The mold pattern may fill the second mold insulating hole 258H. The pre-capacitor electrode on the upper face of the second electrode mold insulating pattern 258 may be removed, using the mold pattern. The second capacitor electrode 255 may be formed, accordingly. The mold pattern may then be removed.

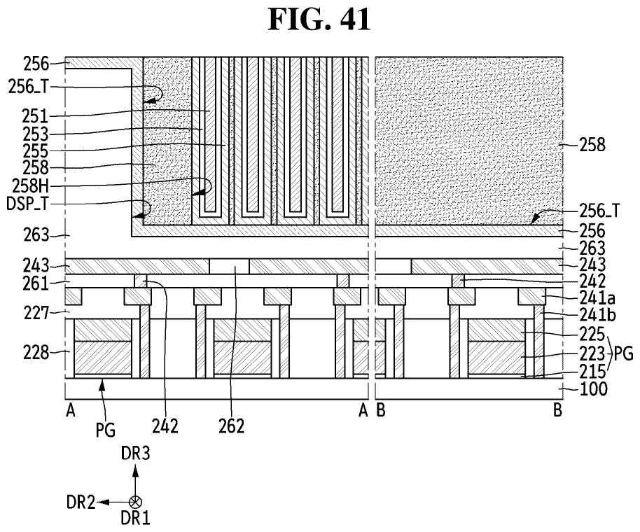

Referring to FIGS. 40 and 41, the capacitor dielectric film 253 may be formed on the second capacitor electrode 255.

The capacitor dielectric film 253 may be formed along the side wall and bottom face of the second mold insulating hole 258H.

Next, the first capacitor electrode 251 may be formed on the capacitor dielectric film 253. The first capacitor electrode 251 may fill the second mold insulating hole 258H.

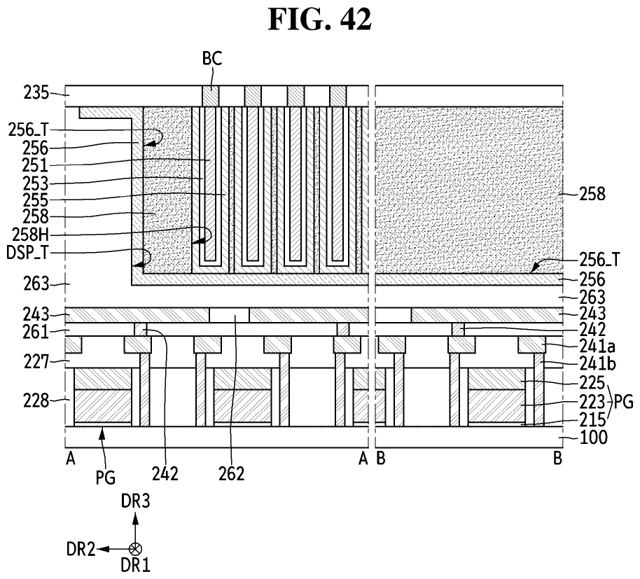

Referring to FIG. 42, the contact separation insulating film 235 may be formed on the second electrode mold insulating pattern 258.

The contact patterns BC may be formed inside the contact separation insulating film 235. The contact pattern BC may be connected to the first capacitor electrode 251.

When the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes.

Although some example embodiments of the present disclosure have been described with reference to the accompanying drawings, the present disclosure is not limited to the above example embodiments but may be implemented in various different forms. A person skilled in the art may appreciate that the present disclosure may be practiced in other concrete forms without changing the technical spirit or essential characteristics of the present disclosure. Therefore, it should be appreciated that the example embodiments as described above are not restrictive but illustrative in all respects.

What is claimed is:

1. A capacitor structure comprising:
a plate electrode defining an electrode mold trench;
an electrode mold insulating pattern in contact with the plate electrode, the electrode mold insulating pattern including a side wall part on a side wall of the electrode mold trench, and a bottom part on a bottom face of the electrode mold trench;
a first capacitor electrode on the bottom part of the electrode mold insulating pattern, and extending in a first direction;
a capacitor dielectric film on the side wall of the first capacitor electrode; and
a second capacitor electrode on the capacitor dielectric film and connected to the plate electrode.

2. The capacitor structure of claim 1,
wherein the bottom part of the electrode mold insulating pattern includes a plurality of sub-electrode insulating patterns spaced apart in a second direction and a third direction that are perpendicular to the first direction.

3. The capacitor structure of claim 2, wherein
each of the sub-electrode insulating patterns includes a first face and a second face that are opposite to each other in the first direction,
the first face of the sub-electrode insulating pattern is in contact with the plate electrode, and
the second face of the sub-electrode insulating pattern is in contact with the first capacitor electrode.

4. The capacitor structure of claim 3, wherein
the sub-electrode insulating pattern includes a side wall that connects the first face of the sub-electrode insulating pattern and the second face of the sub-electrode insulating pattern, and
the second capacitor electrode is in contact with the side wall of sub-electrode insulating pattern.

5. The capacitor structure of claim 1, further comprising:
an electrode support spaced apart from the bottom part of the electrode mold insulating pattern in the first direction, and is in contact with the side wall of the first capacitor electrode.

6. A semiconductor memory device comprising:
a contact pattern on a substrate, the contact pattern including a first face and a second face that are opposite to each other in a first direction;
a capacitor structure between the substrate and the contact pattern and connected to the first face of the contact pattern;
a channel pattern connected to the second face of the contact pattern;
a bit line on the channel pattern and extending in a second direction; and
a word line on the channel pattern between the bit line and the contact pattern, and extending in a third direction,
the capacitor structure including
a plate electrode defining an electrode mold trench,
an electrode mold insulating pattern including a side wall part on a side wall of the electrode mold trench, and a bottom part on a bottom face of the electrode mold trench,
a first capacitor electrode on the bottom part of the electrode mold insulating pattern, and connected to the first face of the contact pattern,
a capacitor dielectric film on the first capacitor electrode, and
a second capacitor electrode on the capacitor dielectric film and connected to the plate electrode.

7. The semiconductor memory device of claim 6, wherein
the first capacitor electrode includes a first face and a second face that are opposite to each other in the first direction,
the second face of the first capacitor electrode is in contact with the contact pattern,
the first face of the first capacitor electrode is in contact with the electrode mold insulating pattern, and
the electrode mold insulating pattern is in contact with the plate electrode.

8. The semiconductor memory device of claim 6, further comprising:
a contact separation insulating film on the first capacitor electrode and the second capacitor electrode, between the capacitor structure and the channel pattern,
wherein the contact pattern is inside the contact separation insulating film, and
the capacitor dielectric film is not along a boundary between the second capacitor electrode and the contact separation insulating film.

9. The semiconductor memory device of claim 6,
wherein the bottom part of the electrode mold insulating pattern includes a plurality of sub-electrode insulating patterns spaced apart from one another.

10. The semiconductor memory device of claim 9, wherein
each of the sub-electrode insulating patterns includes a first face and a second face that are opposite to each other in the first direction, and a side wall that connects the first face of the sub-electrode insulating pattern and the second face of the sub-electrode insulating pattern, and
the capacitor dielectric film does not extend along the side wall of the sub-electrode insulating pattern.

11. The semiconductor memory device of claim 6, further comprising:
an electrode support spaced apart from the bottom part of the electrode mold insulating pattern in the first direction, and is in contact with the side wall of the first capacitor electrode.

12. The semiconductor memory device of claim 6, further comprising:
a peri-gate structure between the substrate and the capacitor structure,
wherein no bonding pad is between the peri-gate structure and the capacitor structure.

13. The semiconductor memory device of claim 6,
wherein the channel pattern includes a vertical part protruding from the second face of the contact pattern in the first direction, and a horizontal part extending along the second face of the contact pattern.

14. The semiconductor memory device of claim 6, wherein
the bit line includes an extension extending in the second direction, and a protrusion protruding in the first direction, and
the protrusion of the bit line protrudes from the extension of the bit line toward the channel pattern.

15. A semiconductor memory device comprising:
a contact pattern on a substrate, the contact pattern including a first face and a second face that are opposite to each other in a first direction;
a capacitor structure between the substrate and the contact pattern and connected to the first face of the contact pattern;
a channel pattern connected to the second face of the contact pattern;
a bit line on the channel pattern and extending in a second direction; and
a word line on the channel pattern between the bit line and the contact pattern and extending in a third direction,
the capacitor structure including
a plate electrode defining an electrode mold trench,
an electrode mold insulating pattern filling the electrode mold trench and including a mold insulating hole,
a first capacitor electrode extending along a side wall and a bottom face of the mold insulating hole, and connected to the plate electrode,
a capacitor dielectric film on the first capacitor electrode, and extending along a side wall and a bottom face of the mold insulating hole, and
a second capacitor electrode on the capacitor dielectric film, filling the mold insulating hole, and connected to the first face of the contact pattern, the bottom face of the mold insulating hole defined by the plate electrode.

16. The semiconductor memory device of claim 15,
wherein the electrode mold insulating pattern is in contact with the plate electrode.

17. The semiconductor memory device of claim 15, wherein
the electrode mold insulating pattern includes a first face and a second face that are opposite to each other in the first direction,
the second face of the electrode mold insulating pattern faces the channel pattern, and
the first capacitor electrode does not cover the second face of the electrode mold insulating pattern.

18. The semiconductor memory device of claim 15,
wherein the channel pattern includes a vertical part protruding from the second face of the contact pattern in the first direction, and a horizontal part extending along the second face of the contact pattern.

19. The semiconductor memory device of claim 15, wherein
the bit line includes an extension extending in the second direction, and a protrusion protruding in the first direction, and
the protrusion of the bit line protrudes from the extension of the bit line toward the channel pattern.

20. The semiconductor memory device of claim 15, further comprising:
a channel insulating film on the second face of the contact pattern, the channel insulating film including a channel trench,
wherein the channel pattern and the word line are inside the channel trench, and
a height from the second face of the contact pattern to a lowermost part of the bit line is smaller than a height from the second face of the contact pattern to an upper face of the channel insulating film.
